(19) United States
(12) Patent Application Publication
(10) Pub. No.: US 2011/0024907 A1
(43) Pub. Date: Feb. 3, 2011

(54) SEMICONDUCTOR DEVICE AND METHOD OF MANUFACTURING THE SAME

(75) Inventor: Yuichiro FUJIYAMA, Kanagawa (JP)

Correspondence Address: MILES & STOCKBRIDGE PC, 1751 PINNACLE DRIVE, SUITE 500, MCLEAN, VA, 22102-3833, US

(73) Assignee: RENESAS ELECTRONICS CORPORATION

(21) Appl. No.: 12/838,446

(22) Filed: Jul. 17, 2010

(30) Foreign Application Priority Data
Jul. 29, 2009 (JP) 2009-176458

(51) Int. Cl. H01L 23/48; H01L 21/768

(52) U.S. Cl. 257/751; 438/627; 257/773; 257/E21.585; 257/E21.584; 257/E23.011

(57) ABSTRACT

To provide a technique capable of improving the reliability on electric properties of a semiconductor device by devising the shape of the upper surface of a plug. A plug of the present invention has an upwardly convex dome-like shape in which the upper surface thereof projects from the surface (upper surface) of a contact interlayer insulating film. That is, the plug has the upper surface of an upwardly convex dome-like shape, wherein the height of the top edge portion of a barrier conductive film is larger than that of the upper surface of the contact interlayer insulating film, and the height of the top edge portion of a tungsten film is larger than that of the top edge portion of the barrier conductive film.

### CROSS-REFERENCE TO RELATED APPLICATION

The disclosure of Japanese Patent Application No. 2009-176458 filed on Jul. 29, 2009 including the specification, drawings and abstract is incorporated herein by reference in its entirety.

The present invention relates to a semiconductor device and a technique of manufacturing the same, particularly, to a semiconductor device having a plug and a technique that is useful when being applied to the manufacturing technique thereof.

### BACKGROUND OF THE INVENTION

Japanese Patent No. 3494275 (Patent Document 1) describes a technique of setting a plug formed over a semiconductor substrate to be higher than an interlayer insulating film, to improve the reliability on the electric connection between a wiring formed over the interlayer insulating film and a plug. It describes such a method of manufacturing the plug that, firstly, a first polishing is performed under a condition in which the polishing speed of a tungsten film is higher than that of the interlayer insulating film and, after that, a second polishing is performed under a condition in which the polishing speed of the tungsten film is lower than that of the interlayer insulating film. On this occasion, in the first polishing, abrasive grains including alumina (Al₂O₃), and such an acidic or basic material as hydrogen peroxide (H₂O₂), potassium hydroxide (KOH) or ammonium hydroxide (NH₄OH) are used, and, in the second polishing, abrasive grains including colloidal silica, and hydrogen peroxide (H₂O₂) or such a basic material as potassium hydroxide (KOH) are used. In the second polishing, the polishing speed of the tungsten film is set to be 50 Å/min, and the polishing speed of the interlayer insulating film is set to be 2500 Å/min.

U.S. Pat. No. 7,291,557 (Patent Document 2) describes a technique for suppressing the deterioration of stress migration (SM) properties or electro migration (EM) properties caused by the occurrence of a void at the end portion of a copper wiring. Specifically, the technique, after performing a first polishing of a copper film so as to terminate it at a barrier conductive film, performs a second polishing of the barrier conductive film so that the copper film becomes a dome shape. On this occasion, it describes that the first polishing is performed under a condition in which the polishing speed of the copper film is higher than that of the interlayer insulating film, and that the second polishing is performed under a condition in which the polishing speed of the barrier conductive film is higher than that of the copper film and that of the interlayer insulating film, and the polishing speed of the interlayer insulating film is higher than that of the copper film.

### SUMMARY OF THE INVENTION

In semiconductor devices, a semiconductor element such as a MISFET (Metal Insulator Semiconductor Field Effect Transistor) is formed over a semiconductor substrate, and an interlayer insulating film is formed so as to cover the semiconductor element. Then, a plug penetrating through the interlayer insulating film is formed, and the bottom surface of the plug is electrically coupled to the source region or drain region of the MISFET. Moreover, wiring is formed over the plug. This gives electric connection of the MISFET and the wiring via the plug. The present inventor found that, on this occasion, the shape of the upper surface of the plug to be connected to the wiring influences the variation in the contact resistance between the wiring and the plug, or the short margin between a wiring insulated from the plug and the plug. That is, the present inventor found that the shape of the upper surface of the plug influences electric properties of a semiconductor device.

The present invention has been made in view of the above circumstances and provides a technique capable of improving the reliability on electric properties of a semiconductor device by devising the shape of the upper surface of a plug.

The other purposes and the new feature of the present invention will become clear from the description of the present specification and the accompanying drawings.

The following explains briefly the outline of a typical invention among the inventions disclosed in the present application.

A semiconductor device according to a representative Example includes (a) a semiconductor element formed over a semiconductor substrate; (b) an interlayer insulating film formed over the semiconductor substrate so as to cover the semiconductor element; (c) a plug penetrating through the interlayer insulating film and electrically coupled to the semiconductor element; and (d) a wiring formed over the interlayer insulating film and electrically coupled to the plug. Further, the plug has (c1) a contact hole formed in the interlayer insulating film, (c2) a barrier conductive film formed on the inner wall of the contact hole, and (c3) a first conductive film formed over the barrier conductive film so as to fill the contact hole. Here, it is characterized in that the upper surface of plug has an upwardly convex dome-like shape projecting from the upper surface of the interlayer insulating film; the height of the top edge portion of the barrier conductive film is larger than that of the upper surface of the interlayer insulating film; and the height of the top edge portion of the first conductive film is larger than that of the top edge portion of the barrier conductive film.

A method of manufacturing a semiconductor device according to a representative Example includes the steps of (a) forming a semiconductor element over a semiconductor substrate; (b) forming an interlayer insulating film over the semiconductor substrate so as to cover the semiconductor element; and (c) forming a contact hole penetrating through the interlayer insulating film. Further, it includes the steps of (d) forming a barrier conductive film over the interlayer insulating film including the inside of the contact hole; (e) forming a first conductive film over the barrier conductive film so as to fill the inside of the contact hole; and (f) thinning the thickness of the first conductive film by a chemical mechanical polishing method. Furthermore, it includes the step of (g), after the step (f), forming a plug by removing a part of the thinned first conductive film, the barrier conductive film and the interlayer insulating film by a chemical mechanical polishing method under a condition in which the polishing speed of the first conductive film is lower than that of the interlayer insulating film, and by leaving the barrier conductive film and the tungsten film in the contact hole. On this occasion, it is characterized in that the upper surface of the plug formed in the step (g) has an upwardly convex dome-like shape projecting from the upper surface of the interlayer insulating film; the height of the top edge portion of the barrier conductive film is larger than that of the upper surface of the interlayer insulating film; and the height of the top edge portion of the first conductive film is larger than that of the top edge portion of the barrier conductive film.

Moreover, a method of manufacturing a semiconductor device according to a representative Example includes the steps of (a) forming a semiconductor element over a semiconductor substrate; (b) forming an interlayer insulating film over the semiconductor substrate so as to cover the semiconductor element; and (c) forming a contact hole penetrating through the interlayer insulating film. Further, it includes the steps of (d) forming a barrier conductive film over the interlayer insulating film including the inside of the contact hole; and (e) forming a first conductive film over the barrier conductive film so as to fill the inside of the contact hole. Furthermore, it includes the steps of (f) exposing the upper surface of the interlayer insulating film by removing the first conductive film and the barrier conductive film formed over the interlayer insulating film by a chemical mechanical polishing method while leaving the barrier conductive film and the first conductive film inside the contact hole. Next, it includes the step of (g), after the step (f), forming a plug by removing apart of the interlayer insulating film by a chemical mechanical polishing method under a condition in which the polishing speed of the first conductive film is lower than that of the interlayer insulating film, and by leaving the barrier conductive film and the tungsten film in the contact hole. On this occasion, it is characterized in that the upper surface of the plug formed in the step (g) has an upwardly convex dome-like shape projecting from the upper surface of the interlayer insulating film; the height of the top edge portion of the barrier conductive film is larger than that of the upper surface of the interlayer insulating film; and the height of the top edge portion of the first conductive film is larger than that of the top edge portion of the barrier conductive film.

Moreover, a method of manufacturing a semiconductor device according to a representative Example includes the steps of (a) forming a semiconductor element over a semiconductor substrate; (b) forming an interlayer insulating film over the semiconductor substrate so as to cover the semiconductor element; and (c) forming a contact hole penetrating through the interlayer insulating film. Further, it includes the steps of (d) forming a barrier conductive film over the interlayer insulating film including the inside of the contact hole; and (e) forming a first conductive film over the barrier conductive film so as to fill the inside of the contact hole. Furthermore, it includes the step of (f) forming a plug by removing a part of the first conductive film, the barrier conductive film and the interlayer insulating film formed over the interlayer insulating film by a chemical mechanical polishing method under a condition in which the polishing speed of the first conductive film is set to be lower than that of the interlayer insulating film while leaving the barrier conductive film and the first conductive film inside the contact hole. On this occasion, it is characterized in that the upper surface of the plug formed in the step (f) has an upwardly convex dome-like shape projecting from the upper surface of the interlayer insulating film; the height of the top edge portion of the barrier conductive film is larger than that of the upper surface of the interlayer insulating film; and the height of the top edge portion of the first conductive film is larger than that of the top edge portion of the barrier conductive film.

The following explains briefly the effect acquired by the typical invention among the inventions disclosed in the present application.

It is possible to improve the reliability on electric properties of a semiconductor device by devising the shape of the upper surface of a plug.

### BRIEF DESCRIPTION OF THE DRAWINGS

FIG. 1 is a cross-sectional view showing the constitution of a semiconductor device in Example 1 of the present invention;

FIG. 2 is a cross-sectional view showing the shape of a plug in a first Comparative Example;

FIG. 3 is a cross-sectional view showing the shape of a plug in a second Comparative Example;

FIG. 4 is a cross-sectional view showing the shape of a plug in Example 1;

FIG. 5 is a cross-sectional view showing a positional relation between a wiring that is originally not connected and a plug, the view showing the comparison of cases where a recess-type, a crown-type and a dome-type plugs are used as the plug;

FIG. 6 is a drawing showing the relation between the amount of plug projection and the normalized amount of the wiring displacement, the drawing showing the comparison of cases where the recess-type, the crown-type and the dome-type plugs are used as the plug;

FIG. 7 is a drawing showing the relation between the normalized value of wiring leak current and the cumulative percentage, the drawing showing the comparison of cases where the recess-type, the crown-type and the dome-type plugs are used as the plug;

FIG. 8 is a cross-sectional view showing the positional relation between the wiring and the plug, the view showing the comparison of cases where the recess-type, the crown-type and the dome-type plugs are used as the plug;

FIG. 9 is a drawing showing the relation between the amount of plug projection and the normalized amount of the wiring displacement, the drawing showing the comparison of cases where the recess-type, the crown-type and the dome-type plugs are used as the plug;

FIG. 10 is a drawing showing the relation between the normalized value of wiring resistance and the cumulative percentage, the drawing showing the comparison of cases where the recess-type, the crown-type and the dome-type plugs are used as the plug;

FIG. 11 is a cross-sectional view illustrating the steps of forming the interlayer insulating film over a contact interlayer insulating film for which the recess-type plug is formed, and forming a wiring trench having displacement for the interlayer insulating film;

FIG. 12 is a cross-sectional view illustrating the steps of forming the interlayer insulating film over the contact interlayer insulating film for which the dome-type plug is formed, and forming a wiring trench having displacement for the interlayer insulating film;

FIG. 13 is a cross-sectional view showing the dimension of the dome-type plug,

FIG. 14 is a cross-sectional view showing a process of manufacturing a semiconductor device in Example 1;

FIG. 15 is a cross-sectional view showing the process of manufacturing a semiconductor device subsequent to FIG. 14;

FIG. 16 is a cross-sectional view showing the process of manufacturing a semiconductor device subsequent to FIG. 15;

FIG. 17 is a cross-sectional view showing the process of manufacturing a semiconductor device subsequent to FIG. 16;

FIG. 18 is a cross-sectional view showing the process of manufacturing a semiconductor device subsequent to FIG. 17;

FIG. 19 is a cross-sectional view showing the process of manufacturing a semiconductor device subsequent to FIG. 18;

FIG. 20 is a cross-sectional view showing the process of manufacturing a semiconductor device subsequent to FIG. 19;

FIG. 21 is a cross-sectional view showing the process of manufacturing a semiconductor device subsequent to FIG. 20;

FIG. 22 is a cross-sectional view showing the process of manufacturing a semiconductor device subsequent to FIG. 21;

FIG. 23 is a cross-sectional view showing the process of manufacturing a semiconductor device subsequent to FIG. 22;

FIG. 24 is a cross-sectional view showing the process of manufacturing a semiconductor device in Example 2;

FIG. 25 is a cross-sectional view showing the process of manufacturing a semiconductor device subsequent to FIG. 24;

FIG. 26 is a cross-sectional view showing an example of a registration mark formed for the semiconductor substrate; and

FIG. 27 is a cross-sectional view showing a state in which erosion has occurred in the registration mark.

### DETAILED DESCRIPTION OF PREFERRED EMBODIMENTS

The following Examples will be explained, divided into plural sections or embodiments, if necessary for convenience. Except for the case where it shows clearly in particular, they are not mutually unrelated and one has relationships such as a modification, details, and supplementary explanation of some or entire of another.

In the following embodiments, when referring to the number of elements, etc. (including the number, a numeric value, an amount, a range, etc.), they may be not restricted to the specific number but may be greater or smaller than the specific number, except for the case where they are clearly specified in particular and where they are clearly restricted to a specific number theoretically.

Furthermore, in the following embodiments, it is needless to say that an element (including an element step etc.) is not necessarily indispensable, except for the case where it is clearly specified in particular and where it is considered to be clearly indispensable from a theoretical point of view, etc.

Similarly, in the Examples below, when the shape, positional relation or the like of an element or the like is referred to, it is intended that one substantially similar or resemblant to it is included, except for such a case as clearly expressed in particular, or clearly considered otherwise in principle. This is just as valid for the numerical value and range.

In all the drawings for explaining embodiments, the same symbol is attached to the same member, as a principle, and the repeated explanation thereof is omitted. In order to make a drawing intelligible, hatching may be attached even if it is a plan view.

### Example 1

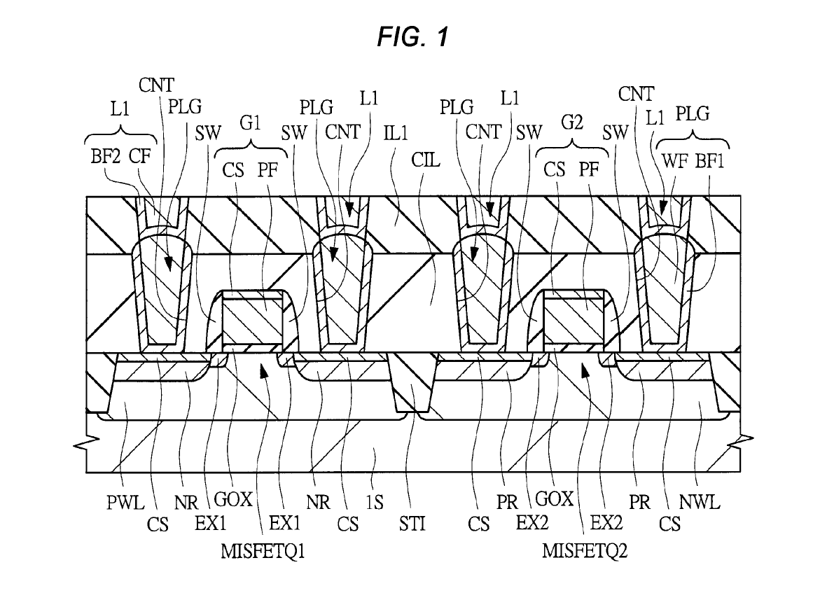

The constitution of a semiconductor device in present Example 1 will be described. FIG. 1 is a cross-sectional view showing the constitution of the semiconductor device in the Example 1. The semiconductor device in the Example 1 has an n-channel type MISFET Q1 and a p-channel type MISFET Q2. Respective constitutions thereof will be described.

Over a semiconductor substrate 1S, a shallow trench isolation region STI for isolating elements is formed. Among active regions divided by the shallow trench isolation region STI, in a region for forming the n-channel type MISFET Q1 (within the semiconductor substrate 1S), a p-type well PWL is formed, and, in a region for forming the p-channel type MISFET Q2 (within the semiconductor substrate 1S), an n-type well NWL is formed.

The n-channel type MISFET Q1 has a gate insulating film GOX over the p-type well PWL formed within the semiconductor substrate 15, and, over the gate insulating film GOX, a gate electrode G1 is formed. The gate insulating film GOX is formed, for example, from a silicon oxide film, and the gate electrode G1 is formed, for example, from a laminated film of a polysilicon film PF and a cobalt silicide film CS, for the sake of lowering the resistance.

The gate electrode G1 has a sidewall SW formed over side walls on both sides thereof, and, within the semiconductor substrate 1S under the sidewall SW, a shallow n-type impurity diffusing region EX1 is formed as a semiconductor region. The sidewall SW is formed, for example, from such an insulating film as a silicon oxide film. And, outside the shallow n-type impurity diffusing region EX1, a deep n-type impurity diffusing region NR is formed, and, over the surface of the deep n-type impurity diffusing region NR, a cobalt silicide film CS is formed.

The sidewall SW is formed in order to give an LDD structure to the source region and drain region being the semiconductor region of the n-channel type MISFET Q1. That is, the source region and drain region of the n-channel type MISFET Q1 are formed from the shallow n-type impurity diffusing region EX1 and the deep n-type impurity diffusing region NR. On this occasion, the shallow n-type impurity diffusing region EX1 has an impurity concentration lower than that of the deep n-type impurity diffusing region NR. Consequently, by setting the source region and drain region under the sidewall SW to be the shallow n-type impurity diffusing region EX1 with a low concentration, it is possible to suppress the electric field concentration under the edge portion of the gate electrode G1.

Next, the p-channel type MISFET Q2 has the gate insulating film GOX over the n-type well NWL formed within the semiconductor substrate 15, and, over the gate insulating film GOX, a gate electrode G2 is formed. The gate insulating film GOX is formed, for example, from a silicon oxide film, and the gate electrode G2 is formed, for example, from a laminated film of the polysilicon film PF and the cobalt silicide film CS for the sake of lowering the resistance.

The gate electrode G2 has a sidewall SW formed over side walls on both sides thereof, and, within the semiconductor substrate 1S under the sidewall SW, a shallow p-type impurity diffusing region EX2 is formed as a semiconductor region. The sidewall SW is formed, for example, from such an insulating film as a silicon oxide film. And, outside the shallow p-type impurity diffusing region EX2, a deep p-type impurity diffusing region PR is formed, and, over the surface of the deep p-type impurity diffusing region PR, a cobalt silicide film CS is formed.

The sidewall SW is formed in order to give an LDD structure to the source region and drain region being the semiconductor region of the p-channel type MISFET Q2. That is, the source region and drain region of the p-channel type MISFET Q2 are formed from the shallow p-type impurity diffusing region EX2 and the deep n-type impurity diffusing region PR. On this occasion, the shallow p-type impurity diffusing region EX2 has an impurity concentration lower than that of the deep p-type impurity diffusing region PR. Consequently, by setting the source region and drain region under the sidewall SW to be the shallow P-type impurity diffusing region EX2 with a low concentration, it is possible to suppress the electric field concentration under the edge portion of the gate electrode G2.

As described above, the n-channel type MISFET Q1 and the p-channel type MISFET Q2 are formed over the semiconductor substrate 1S. So as to cover the n-channel type MISFET Q1 and the p-channel type MISFET Q2, the contact interlayer insulating film CIL constituted, for example, from a silicon oxide film is formed, and, so as to penetrate through the contact interlayer insulating film CIL, a contact hole CNT is formed. The contact hole CNT is formed so as to reach the source region and drain region of the n-channel type MISFET Q1, or the source region and drain region of the p-channel type MISFET Q2. Within the contact hole CNT, a plug PLG is formed. The plug PLG is formed by filling up a barrier conductive film BF1 including a titanium/titanium nitride film (a titanium film and a titanium nitride film formed over the titanium film), and a tungsten film WF within the contact hole CNT.

Further, over the contact interlayer insulating film CIL for which the plug PLG is formed, the interlayer insulating film IL1 is formed. The interlayer insulating film IL1 is also formed, for example, from a silicon oxide film. For the interlayer insulating, film IL1, a wiring trench is formed, and a wiring L1 is formed so as to fill up the wiring trench. The wiring L1 is formed by filling up a barrier conductive film BF2 constituted of, for example, a tantalum/tantalum nitride film (a tantalum nitride film and a tantalum film over the tantalum nitride film), and a copper film CF in the wiring trench. In this way, consequently, the source region and drain region of the n-channel type MISFET Q1 and the source region and drain region of the p-channel type MISFET Q2 are electrically coupled to the wiring L1 via the plug PLG.

Here, the Example 1 is characterized in the point that the shape of the plug PLG is devised. Specifically, the characteristic point of the Example 1 is that the upper surface of the plug PLG has an upwardly convex dome-like shape. By forming the plug PLG in this manner, the reliability on electric properties of the semiconductor device may be improved. Hereinafter, the fact that the plug PLG in the Example 1 may improve the reliability on electric properties of the semiconductor device will be described, while comparing it with Comparative Example.

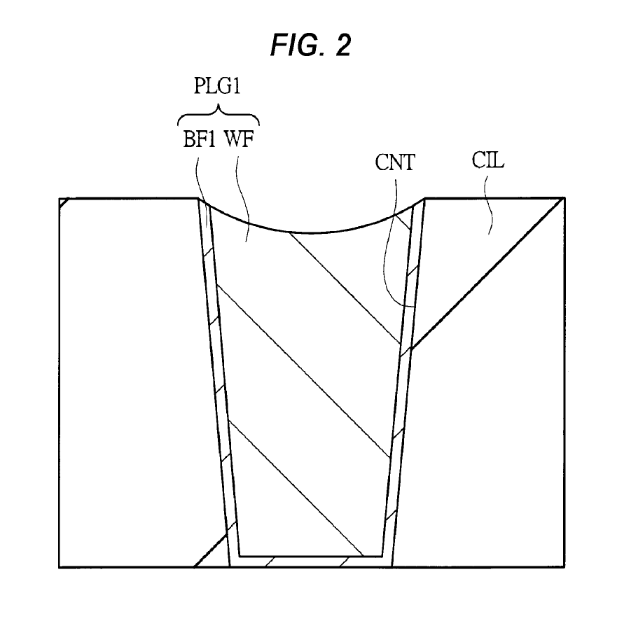

Firstly, the structure of a plug PLG1 in a first Comparative Example will be described. FIG. 2 is a cross-sectional view showing the structure of the plug PLG1 in a first Comparative Example. In FIG. 2, for the contact interlayer insulating film CIL, the contact hole CNT is formed. And, over the inner wall of the contact hole CNT, the barrier conductive film BF1 is formed, and, further, over the barrier conductive film BF1, the tungsten film WF is formed so as to fill up the contact hole CNT. In this manner, by filling up the contact hole CNT with the tungsten film WF via the barrier conductive film BF1, the plug PLG1 is formed. On this occasion, the plug PLG1 in the first Comparative Example has such a shape that the upper surface thereof is more concave than the surface (the upper surface) of the contact interlayer insulating film CIL.

It is desirable that the upper surface of the plug PLG1 and the surface (upper surface) of the contact interlayer insulating film CIL are formed so as to become in a straight line. Since a chemical mechanical polishing (CMP) method is used, however when the plug PLG1 is formed, even when the upper surface of the plug PLG1 is tried to be the same level as the surface (upper surface) of the contact interlayer insulating film CIL, actually, as shown in FIG. 2, the upper surface of the plug PLG1 has a concave shape from the surface of the contact interlayer insulating film CIL. That is, in an ordinary process of forming the plug, even when the upper surface of the plug PLG1 is tried to be the same level as the upper surface of the contact interlayer insulating film CIL, a shape is given in which the upper surface of the plug PLG is concave from the upper surface of the contact interlayer insulating film CIL.

The mechanism thereof is shown below. For example, after forming the contact hole CNT in the contact interlayer insulating film CIL, the barrier conductive film BF1 and the tungsten film WF are formed over the contact interlayer insulating film CIL including the inside of the contact hole CNT. Then, an unnecessary tungsten film WF and barrier conductive film BF1 formed over the contact interlayer insulating film CIL are removed by a CMP method. As the result, the plug PLG1 wherein the barrier conductive film BF1 and the tungsten film WF are embedded only in the contact hole CNT may be formed. On this occasion, at the surface of the contact hole CNT, the tungsten film WF formed over the surface of the contact hole CNT is excessively scraped because a mechanical polishing pressure due to CMP is applied. This phenomenon is referred to as dishing, and, by the dishing, the upper surface of the plug PLG1 becomes more concave than the upper surface of the contact interlayer insulating film CIL. As described above, the plug PLG1 formed by an ordinary process has a shape of a concave upper surface. The plug PLG1 having the shape of a concave upper surface is defined as a plug in the first Comparative Example. Hereinafter, the plug PLG1 having the shape of a concave upper surface is referred to as a recess-type plug.

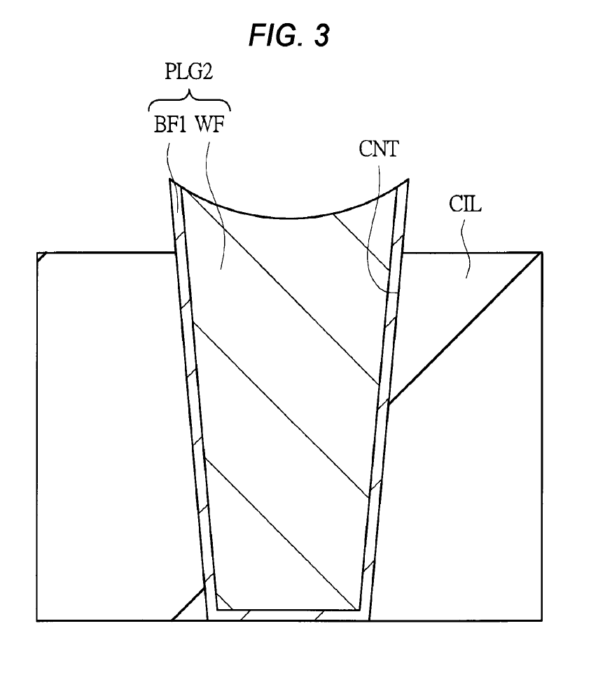

Next, the structure of a plug PLG2 in a second Comparative Example will be described. FIG. 3 is a cross-sectional view showing the structure of the plug PLG2 in the second Comparative Example. In FIG. 3, for the contact interlayer insulating film CIL, the contact hole CNT is formed. And, over the inner wall of the contact hole CNT, the barrier conductive film BF1 is formed, and, so as to fill up the contact hole CNT, the tungsten film WF is formed over the barrier conductive film BF1. As described above, by filling up the contact hole CNT with the tungsten film WF via the barrier conductive film BF1, the plug PLG2 is formed. On this occasion, the plug PLG2 in the second Comparative Example has such a shape that the upper surface thereof projects from the surface (upper surface) of the contact interlayer insulating film CIL.

The plug PLG2 in the second Comparative Example was attempted in order to improve the plug PLG1 in the first Comparative Example. That is, the plug PLG1 in the first Comparative Example has such an upper surface as more concave than the surface of the contact interlayer insulating film CIL. Therefore, in the case of the plug PLG2 in the second Comparative Example, processing is performed so that the upper surface of the plug PLG2 does not become lower than the upper surface of the contact interlayer insulating film CIL. Hereinafter, the processing method will be described.

For example, after forming the contact hole CNT in the interlayer insulating film CIL, the barrier conductive film BF1 and the tungsten film WF are formed over the contact interlayer insulating film CIL including the inside of the contact hole CNT. Then, an unnecessary tungsten film WF and barrier conductive film BF1 formed over the contact interlayer insulating film CIL are removed by a CMP method. As the result, the plug PLG2 wherein the barrier conductive film BF1 and the tungsten film WF are embedded only in the contact hole CNT may be formed. On this occasion, at the surface of the contact hole CNT, the tungsten film WF formed over the surface of the contact hole CNT is excessively scraped because a mechanical polishing pressure due to CMP is applied. That is, by the dishing, the upper surface of the plug PLG2 becomes more concave than the upper surface of the contact interlayer insulating film CIL. Accordingly, in the second Comparative Example, for the purpose of not allowing the upper surface of the plug PLG2 to be more concave than the upper surface of the contact interlayer insulating film CIL, after forming the plug PLG2, the contact interlayer insulating film CIL is etched. As shown in FIG. 3, this makes the upper surface of the plug PLG2 higher than the upper surface of the contact interlayer insulating film CIL. That is, in the second Comparative Example, a structure, in which a part of the plug PLG2 projects from the upper surface of the contact interlayer insulating film CIL, is given. As described above, in the second Comparative Example, the structure, where the upper surface of the plug PLG2 projects from the upper surface of the contact interlayer insulating film CIL, is given, but, since only the contact interlayer insulating film CIL is etched, a concave shape due to the dishing is maintained in the shape of the upper surface of the plug PLG2. Accordingly, the plug PLG2 in the second Comparative Example has such a structure that the top edge portion of the plug PLG2 projects from the contact interlayer insulating film CIL, and that, in addition, the upper surface of the projecting plug PLG2 is concave while reflecting the concave due to the dishing, to result in a crown shape. In the plug PLG2 of the crown shape, the height of the top edge portion of the barrier conductive film BF1 is higher than that of the upper surface of the contact interlayer insulating film CIL, and the height of the top edge portion of the tungsten film WF is lower than that of the top edge portion of the barrier conductive film BF1. The plug PLG2 of the crown shape is defined as the plug in the second Comparative Example. Hereinafter, the plug PLG2 of the crown shape is referred to as the crown-type plug.

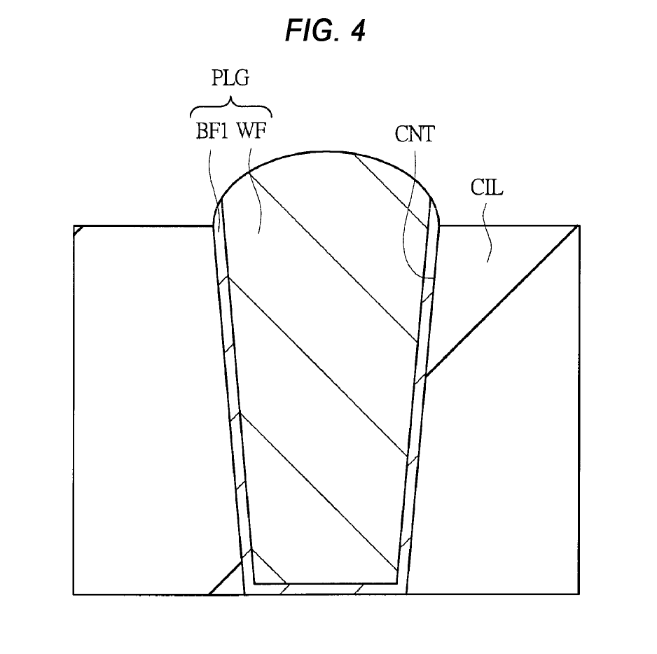

Subsequently, the structure of the plug PLG in the Example will be described. FIG. 4 is a cross-sectional view showing the structure of the plug PLG in the Example. In FIG. 4, in the contact interlayer insulating film CIL, the contact hole CNT is formed. And, over the inner wall of the contact hole CNT, the barrier conductive film BF1 is formed, and, so as to fill up the contact hole CNT, the tungsten film WF is formed over the barrier conductive film BF1. As described above, by filling up the contact hole CNT with the tungsten film WF via the barrier conductive film BF1, the plug PLG is formed. On this occasion, the plug PLG in the Example 1 has such an upwardly convex dome-like shape that the upper surface projects from the surface (upper surface) of the contact interlayer insulating film CIL. That is, the upper surface of the plug PLG in the Example 1 is formed with an upwardly convex curved plane, wherein the height of the top edge portion of the barrier conductive film BF1 is higher than that of the upper surface of the contact interlayer insulating film CIL, and the height of the top edge portion of the tungsten film WF is higher than that of the top edge portion of the barrier conductive film BF1.

As described above, the plug PLG in the Example 1 has, as with the plug PLG2 in the second Comparative Example, the top edge portion of the plug (plug PLG, plug PLG2) projecting from the upper surface of the contact interlayer insulating film CIL. However, the difference in the plug PLG in the Example 1 from the plug PLG2 in the second Comparative Example is the shape of the top edge portion of the plug projecting from the contact interlayer insulating film CIL. That is, in the plug PLG2 in the second Comparative Example, the shape of the top edge portion projecting from the contact interlayer insulating film CIL is the crown shape, but, in the plug PLG in the Example 1, the shape of the top edge portion projecting form the contact interlayer insulating film CIL is the upwardly convex dome-like shape. In other words, in the plug PLG2 in the second Comparative Example, the height of the top edge portion of the barrier conductive film BF1 is higher than that of the upper surface of the contact interlayer insulating film CIL, and the height of the top edge portion of the tungsten film WF is lower than that of the top edge portion of the barrier conductive film BF1. In contrast, in the plug PLG in the Example 1, the height of the top edge portion of the barrier conductive film BF1 is higher than that of the upper surface of the contact interlayer insulating film CIL, and the height of the top edge portion of the tungsten film WF is higher than that of the top edge portion of the barrier conductive film BF1. Hereinafter, the plug PLG of the dome shape is referred to as the dome-type plug.

As described above, the first Comparative Example gives the recess-type plug (plug PLG1), and the second Comparative Example gives the crown-type plug (PLG2). And, the Example gives the dome-type plug (plug PLG). Here, the recess-type plug (plug PLG1), the crown-type plug (plug PLG2), and the dome-type plug (plug PLG) give different influences on electric properties of a semiconductor device. Specifically, the dome-type plug (plug PLG) may improve electric properties of a semiconductor device, as compared with the recess-type plug (plug PLG1) and the crown-type plug (plug PLG2). This will be described with reference to drawings.

In the upper layer of the plug, a wiring layer is formed and the wiring is electrically coupled to the plug, wherein a plurality of wirings is formed over the plug. That is, among the wirings formed over the plug, there lies a wiring to be connected to the plug, and lies a wiring not connected to the plug. For example, when the wirings are formed adjacently, among the wirings, a specified wiring is electrically coupled to the plug. And a wiring adjacent to the specified wiring is occasionally not connected to the plug. On this occasion, when the interval between adjacent wirings becomes small along with the miniaturization of a semiconductor device, the interval between a wiring not connected to the plug and the plug becomes small. Further, the wiring is formed through patterning by a photolithographic technique, but, in the photolithographic technique, pattern displacement occurs. Accordingly, the contact between the plug and a wiring that is originally not to be connected to the plug could occur caused by the pattern displacement in the photolithographic technique. On this occasion, a leak current flows between the wiring that is originally not connected to the plug and the plug, to deteriorate electric properties of the semiconductor device. Consequently, the plug desirably has such a structure that a wiring that is originally not connected to the plug hardly contacts to the plug even when the pattern displacement in the photolithographic technique occurs.

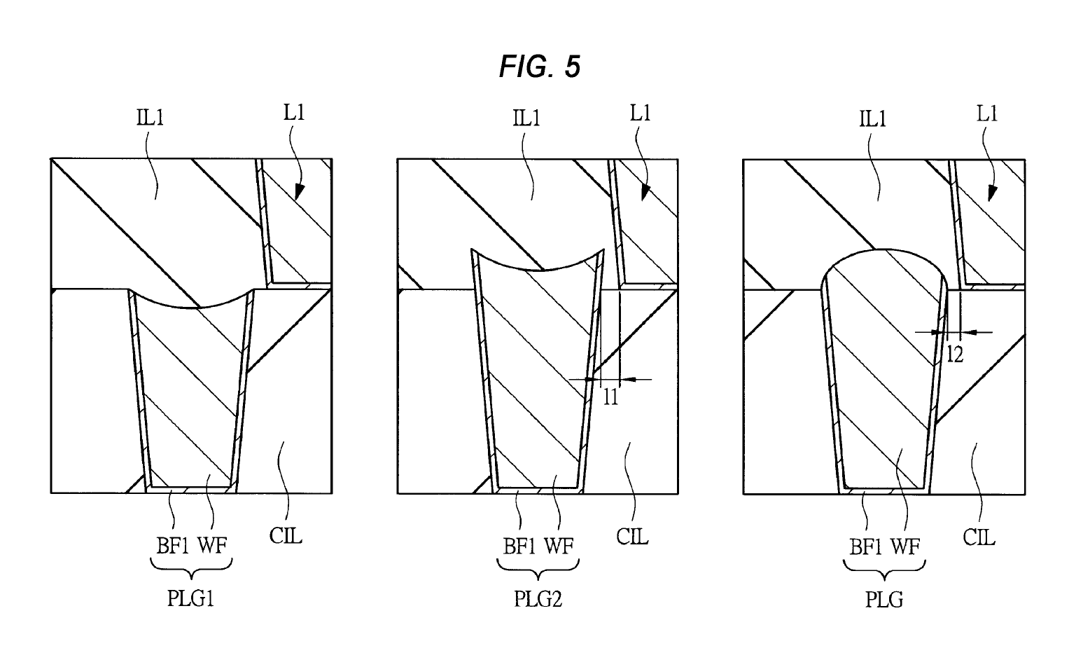

FIG. 5 is a cross-sectional view showing the positional relation between a wiring L1 that is originally not connected and the plug, wherein the drawing compares a case where the recess-type plug (plug PLG1) is used, a case where the crown-type plug (plug PLG2) is used, and a case where the dome-type plug (plug PLG) is used, as the plug. In FIG. 5, the case where the recess-type plug (plug PLG1) is used is shown on the left side, and the case where the crown-type plug (plug PLG2) is used is shown at the center. And, the case where the dome-type plug (plug PLG) is used is shown on the right side. Meanwhile, in FIG. 5, for the purpose of making the positional relation between the plug and the wiring L1 that is originally not connected to the plug understandable clearly, a wiring connected to the plug is not shown.

From FIG. 5, it is qualitatively understood that the dome-type plug (plug PLG) is hardly contacted to the wiring L1 that is originally not connected, as compared with the crown-type plug (plug PLG2). Firstly, the positional relation between the crown-type plug (plug PLG2) and the wiring L1 that is originally not connected, which is shown at the center of FIG. 5, will be described. As shown at the center of FIG. 5, the crown-type plug (plug PLG2) is formed in the contact interlayer insulating film CIL, wherein the top edge portion of the crown-type plug (plug PLG2) projects from the contact interlayer insulating film CIL. Over the crown-type plug (plug PLG2) having the projecting top edge portion, the interlayer insulating film IL1 is formed, and the wiring L1 is formed so as to fill up the interlayer insulating film IL1. On this occasion, the projecting top edge portion of the crown-type plug (plug PLG2) has a crown shape that broadens toward the outside along with the upward extension. At the same time, the wiring L1 that is originally not connected to the plug also has such a shape that broadens toward the upside. Consequently, it is understood that, even when the interval 11 between the crown-type plug (plug PLG2) and the wiring L1 at the upper surface of the contact interlayer insulating film CIL is large, they contact to each other. That is, in the crown-type plug (plug PLG2), it is understood that, only when the position of the wiring L1 that is originally not connected is displaced in a slight amount, the wiring L1 is contacted to the crown-type plug (plug PLG2) in the end. That is, it is understood that, in the crown-type plug (plug PLG2), a probability of the contact is high even when the displacement of the wiring L1 that is originally not connected is small, and that the displacement margin of the wiring L1 for a short circuit defect becomes small.

Next, the positional relation between the dome-type plug (plug PLG) and the wiring L1 that is originally not connected, which is shown on the right side of FIG. 5, will be described. As shown on the right side of FIG. 5, the dome-type plug (plug PLG) is formed in the contact interlayer insulating film CIL, and the top edge portion of the dome-type plug (plug PLG) projects from the contact interlayer insulating film CIL. Over the dome-type plug (plug PLG) having the projecting top edge portion, the interlayer insulating film IL1 is formed, and the wiring L1 is formed so as to be embedded in the interlayer insulating film IL1. On this occasion, the projecting top edge portion of the dome-type plug (plug PLG) has the upwardly convex dome-like shape, and, differing from the projecting top edge portion of the crown-type plug (plug PLG2), does not have such a shape that broadens outward along with the upward extension. Accordingly, it is understood that the wiring L1 is hardly contacted to the dome-type plug (plug PLG) even when the interval 12 between these is small at the upper surface of the contact interlayer insulating film CIL. That is, it is understood that, in the case of the dome-type plug (plug PLG), the dome-type plug (plug PLG) and the wiring L1 are arranged so that they hardly contact to each other even when the position of the wiring L1 that is originally not connected displaces largely. Briefly, it is understood that, in the dome-type plug (plug PLG), a probability of the contact is low even when the displacement of the wiring L1 that is originally not connected is large, and that the displacement margin of the wiring L1 for the short circuit defect may be made large.

From the above, it is understood that the dome-type plug (plug PLG) has such a structure that the short circuit defect with the wiring L1 that is originally not connected hardly occurs as compared with the crown-type plug (plug PLG2). In other words, the dome-type plug (plug PLG) may set the margin for the displacement of the wiring L1 that is originally not connected to be large as compared with the crown-type plug (plug PLG2). This means that the short circuit defect between the plug and the wiring L1 that is originally not connected may sufficiently be suppressed even when the displacement of the wiring L1 caused by the photolithographic technique occurs, and that the improvement of the reliability on electric properties in the semiconductor device may be achieved. That is, according to the dome-type plug (plug PLG) such as that in the Example 1, even when some degree of variation occurs in the formation position of the wiring L1 that is originally not connected, due to the photolithographic technique, the fluctuation of electric properties caused by the variation may be suppressed.

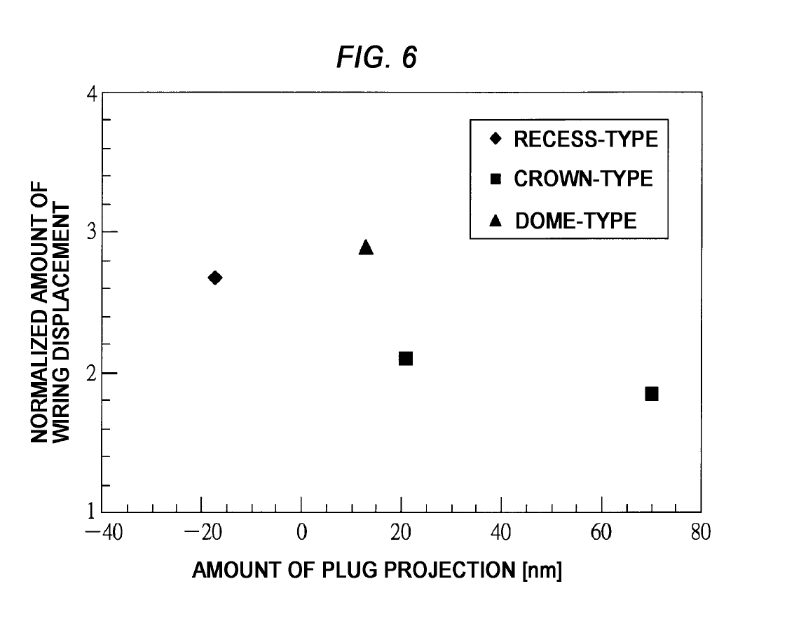

Hereinafter, the result of the inspection that, among the recess-type plug (plug PLG1), the crown-type plug (plug PLG2) and the dome-type plug (plug PLG), the dome-type plug (plug PLG) may set the margin for the wiring displacement to be largest. FIG. 6 is a graph showing the relation between the amount of the plug projection (nm) and the normalized amount of the wiring displacement in the recess-type plug (plug PLG1), the crown-type plug (plug PLG2) and the dome-type plug (plug PLG). In FIG. 6, the horizontal axis shows the amount of the plug projection from the contact interlayer insulating film CIL, and the vertical axis shows the normalized amount of the wiring displacement where the wiring does not contact to the plug even when the formation position of a wiring that is originally not connected to the plug is displaced from a designed value. Accordingly, a large amount of the wiring displacement means that the amount of the wiring displacement of the wiring that is originally not connected to the plug is large until it is contacted to the plug, and shows that the wiring that is originally not connected to the plug hardly contacts to it. That is, it means that, when the amount of the wiring displacement shown on the vertical axis becomes large, the wiring that is originally not connected to the plug is hardly contacted to the plug to suppress the short circuit defect, in other words, the increase in the leak current. Meanwhile, in FIG. 6, the plot of a rhombus represents the recess-type plug (plug PLG1), and the plot of squares represents the crown-type plug (plug PLG2). Moreover, the plot of a triangle represents the dome-type plug (plug PLG).

When observing FIG. 6 while considering the above, it is understood that the amount of the wiring displacement of the dome-type plug (plug PLG) is larger than that of the wiring displacement in the recess-type plug (plug PLG1) or that of the wiring displacement in the crown-type plug (PLG2). It is understood that this makes the dome-type plug (plug PLG) have a larger amount of the wiring displacement until the wiring that is originally not connected to the plug is contacted to the plug, as compared with the recess-type plug (plug PLG1) and the crown-type plug (plug PLG2), and that the wiring that is originally not connected to the plug hardly contacts to the plug. Consequently, it is understood that the dome-type plug (plug PLG) may sufficiently suppress the short circuit defect between the plug and the wiring that is originally not connected even when the displacement of the wiring caused by the photolithographic technique occurs, and that the improvement of the reliability on electric properties in the semiconductor device may be achieved.

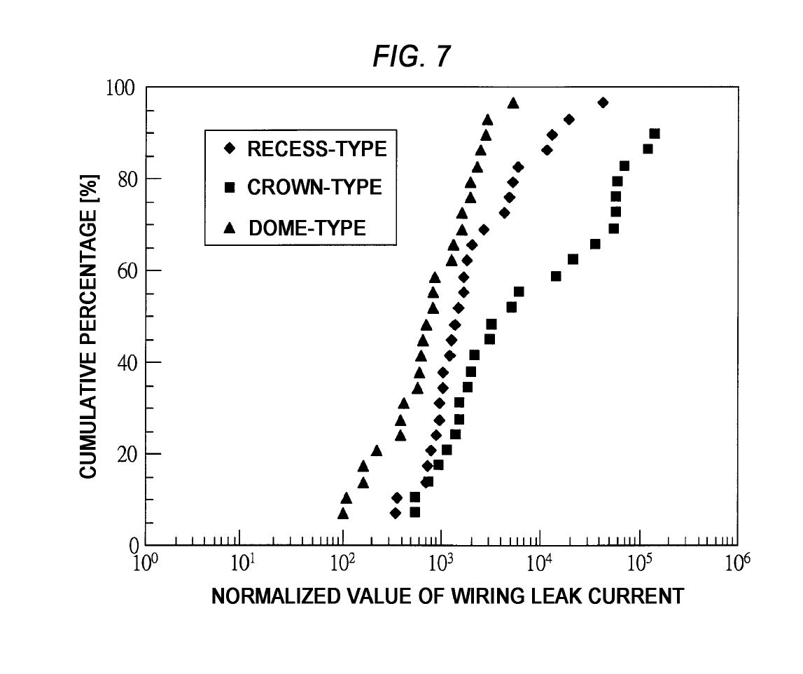

Next, the result of the inspection that, among the recess-type plug (plug PLG1), the crown-type plug (plug PLG2) and the dome-type plug (plug PLG), the dome-type plug (plug PLG) may set the variation in the value of the wiring leak current to be smallest. FIG. 7 is a graph showing the relation between the normalized value of a wiring leak current and the cumulative percentage in the recess-type plug (plug PLG1), the crown-type plug (plug PLG2) and the dome-type plug (plug PLG). In FIG. 7, the horizontal axis shows the normalized value of the wiring leak current, and the vertical axis shows the cumulative percentage of test objects. The cumulative percentage means that, for example, when 1000 semiconductor chips are set to be test objects, cumulative percentage 50% represents the variation in the value of the wiring leak current for 500 semiconductor chips, and cumulative percentage 100% represents the variation in the value of the wiring leak current for 1000 semiconductor chips. In the graph shown in FIG. 7, a plot of the graph that stands more vertically means a less variation, and that a plot more shifting toward the left side means a less value of the wiring leak current. Meanwhile, in FIG. 7, the plot of rhombuses corresponds to the recess-type plug (plug PLG1), and the plot of squares corresponds to the crown-type plug (plug PLG2). Moreover, the plot of triangles corresponds to the dome-type plug (plug PLG).

When observing FIG. 7 while considering the above, firstly, it is understood that, among the recess-type plug (plug PLG1), the crown-type plug (plug PLG2) and the dome-type plug (plug PLG), the plot of the dome-type plug (plug PLG) stands most vertically. This means that the use of the dome-type plug (plug PLG) may make the variation in the value of the wiring leak current small. That is, it is understood that, according to the dome-type plug (plug PLG) in the Example 1, even when some degree of variation occurs in the formation position of the wiring that is originally not connected due to the photolithographic technique, the fluctuation of electric properties (for example, value of the wiring leak current) based on the variation may be suppressed.

Further, from FIG. 7, the dome-type plug (plug PLG) shows the smallest absolute value of the wiring leak current. From this, it is understood that, according to the dome-type plug (plug PLG), even when the displacement of the wiring due to the photolithographic technique occurs, the short circuit defect between the plug and the wiring that is originally not connected may sufficiently be suppressed and the improvement of the reliability on electric properties in the semiconductor device may be achieved.

As described above, it is understood that, among the recess-type plug (plug PLG1), the crown-type plug (plug PLG2) and the dome-type plug (plug PLG), the dome-type plug (plug PLG) is best from the standpoint of reducing the leak current between the wiring that is originally not connected to the plug and the plug, and of reducing the variation in the value of the wiring leak current even when the formation displacement due to the photolithographic technique occurs.

Next, as an example showing that the dome-type plug (plug PLG) may improve electric properties of the semiconductor device as compared with the recess-type plug (plug PLG1) and the crown-type plug (plug PLG2), an explanation will be given while taking the wiring resistance between a plug and a wiring electrically coupled to the plug as an example.

Usually, a wiring is formed over a plug, and the wiring is electrically coupled to the plug. The wiring is formed by patterning using a photolithographic technique, which generates a pattern displacement. Accordingly, the pattern displacement due to the photolithographic technique generates the change of the contact area between the plug and the wiring. On this occasion, the wiring resistance between the wiring and the plug changes to deteriorate electric properties of the semiconductor device. Consequently, the plug desirably has such a structure that hardly changes the wiring resistance between the plug and the wiring even when the pattern displacement due to the photolithographic technique occurs.

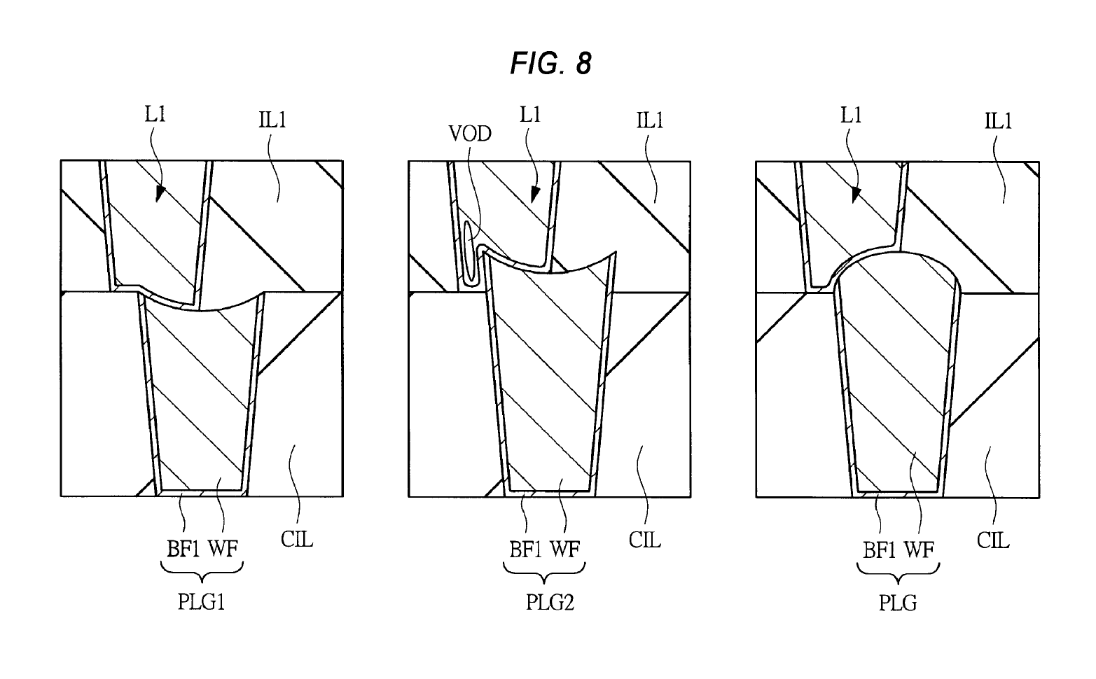

FIG. 8 is a cross-sectional view showing the positional relation between a wiring L1 and the plug, wherein the drawing compares a case where the recess-type plug (plug PLG1) is used, a case where the crown-type plug (plug PLG2) is used, and a case where the dome-type plug (plug PLG) is used, as the plug. In FIG. 8, the case where the recess-type plug (plug PLG1) is used is shown on the left side, and the case where the crown-type plug (plug PLG2) is used is shown at the center. And, the case where the dome-type plug (plug PLG) is used is shown on the right side.

Firstly, the positional relation between the crown-type plug (plug PLG2) and the wiring L1 that is connected, which is shown at the center of FIG. 8, will be described. As shown at the center of FIG. 8, the crown-type plug (plug PLG2) is formed in the contact interlayer insulating film CIL, wherein the top edge portion of the crown-type plug (plug PLG2) projects from the contact interlayer insulating film CIL. Over the crown-type plug (plug PLG2) having the projecting top edge portion, the interlayer insulating film IL1 is formed, and the wiring L1 is formed so as to be embedded in the interlayer insulating film IL1. On this occasion, the projecting top edge portion of the crown-type plug (plug PLG2) has a crown shape that broadens toward the outside along with the upward extension. Accordingly, for example, as shown at the center in FIG. 8, a case where the position of the wiring L1 displaces toward the left side from the position of the crown-type plug (plug PLG2). In this case, the top edge portion of the crown-type plug (plug PLG2) that projects in an acute angle cuts into the inside of a wiring trench for forming the wiring L1. As the result, a copper film may not sufficiently be embedded into the wiring trench to heighten the risk of the generation of a void VOD. The generation of such void VOD largely changes the wiring resistance. That is, it is understood that, in the crown-type plug (plug PLG2), there is such possibility that the wiring resistance becomes large only when the position of the wiring L1 to be connected to the crown-type plug (plug PLG2) displaces slightly. Briefly, it is understood that, in the crown-type plug (plug PLG2), there is such probability that the wiring resistance changes largely even when the displacement of the wiring L1 is small, and that the displacement margin of the wiring L1 relative to the change of the wiring resistance is small.

Next, the positional relation between the dome-type plug (plug PLG) and the wiring L1, which is shown on the right side of FIG. 8, will be described. As shown on the right side of FIG. 8, the dome-type plug (plug PLG) is formed in the contact interlayer insulating film CIL, and the top edge portion of the dome-type plug (plug PLG) projects from the contact interlayer insulating film CIL. Over the dome-type plug (plug PLG) having the projecting top edge portion, the interlayer insulating film IL1 is formed, and the wiring L1 is formed so as to be embedded in the interlayer insulating film IL1. On this occasion, the projecting top edge portion of the dome-type plug (plug PLG) has the upwardly convex dome-like shape, and, differing from the projecting top edge portion of the crown-type plug (plug PLG2), does not have such a shape that broadens outward along with the upward extension. In other words, the dome-type plug (plug PLG) does not have a portion that projects in an acute angle shape. Consequently, the copper film may sufficiently be embedded into the wiring trench even when the displacement of the wiring L1 occurs, to lower the risk of the generation of the void VOD. Accordingly, the change of the wiring resistance is not so large as that in the crown-type plug (plug PLG2). That is, in the dome-type plug (plug PLG), the change of the wiring resistance does not become large as compared with the crown-type plug (plug PLG2) even when the position of the wiring L1 connected to the dome-type plug (plug PLG) displaces to some degree. Briefly, in the dome-type plug (plug PLG), the change of the wiring resistance is small even when the displacement of the wiring L1 occurs, and it is possible to set the displacement margin of the wiring L1 relative to the change of the wiring resistance to be large.

From the above, it is understood that the dome-type plug (plug PLG) has such a structure that the change of the wiring resistance between the wiring L1 and the plug hardly occurs as compared with the crown-type plug (plug PLG2). In other words, the dome-type plug (plug PLG) may set the margin for the displacement of the wiring L1 to be large as compared with the crown-type plug (plug PLG2). This means that the increase in the wiring resistance between the plug and the wiring L1 may sufficiently be suppressed even when the displacement of the wiring L1 caused by the photolithographic technique occurs, and that the improvement of the reliability on electric properties in the semiconductor device may be achieved. That is, according to the dome-type plug (plug PLG) such as that in the Example 1, even when some degree of variation occurs in the formation position of the wiring L1 due to the photolithographic technique, the fluctuation of electric properties caused by the variation may be suppressed.

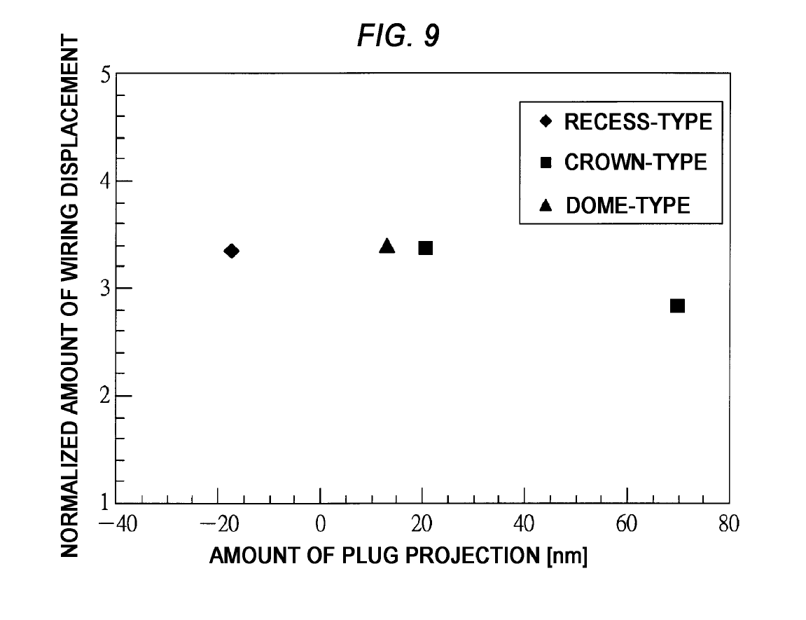

Hereinafter, the result of the inspection that, among the recess-type plug (plug PLG1), the crown-type plug (plug PLG2) and the dome-type plug (plug PLG), the dome-type plug (plug PLG) may set the margin for the wiring displacement to be largest. FIG. 9 is a graph showing the relation between the amount of the plug projection (nm) and the normalized amount of the wiring displacement in the recess-type plug (plug PLG1), the crown-type plug (plug PLG2) and the dome-type plug (plug PLG). In FIG. 9, the horizontal axis shows the amount of the plug projection from the contact interlayer insulating film CIL, and the vertical axis shows the normalized amount of the wiring displacement that allows the wiring resistance between the plug and the wiring to lie within a prescribed range even when the formation position of the wiring to be connected to the plug displaces from a designed value. Accordingly, a large amount of the wiring displacement means that the amount of the wiring displacement, which results in the wiring resistance between the wiring and the plug that exceeds a prescribed range, is large, and shows that the change of the wiring resistance between the wiring and the plug is small. Meanwhile, in FIG. 9, the plot of a rhombus represents the recess-type plug (plug PLG1), and the plot of squares represents the crown-type plug (plug PLG2). Moreover, the plot of a triangle represents the dome-type plug (plug PLG).

When observing FIG. 9 while considering the above, it is understood that the amount of the wiring displacement in the dome-type plug (plug PLG) is approximately the same as that of the wiring displacement in the recess-type plug (plug PLG1), but that it is larger than the amount of the wiring displacement in the crown-type plug (PLG2). Consequently, it is understood that the dome-type plug (plug PLG) has a larger amount of the wiring displacement until the wiring resistance between the wiring and the plug exceeds a prescribed range as compared with the crown-type plug (plug PLG2), and that the wiring resistance between the wiring and the plug hardly changes. From this, it is understood that, according to the dome-type plug (plug PLG), the change of the wiring resistance between the plug and the wiring may be made small even when the displacement of the wiring due to the photolithographic technique occurs, and that it is possible to achieve the improvement of the reliability on electric properties in a semiconductor device.

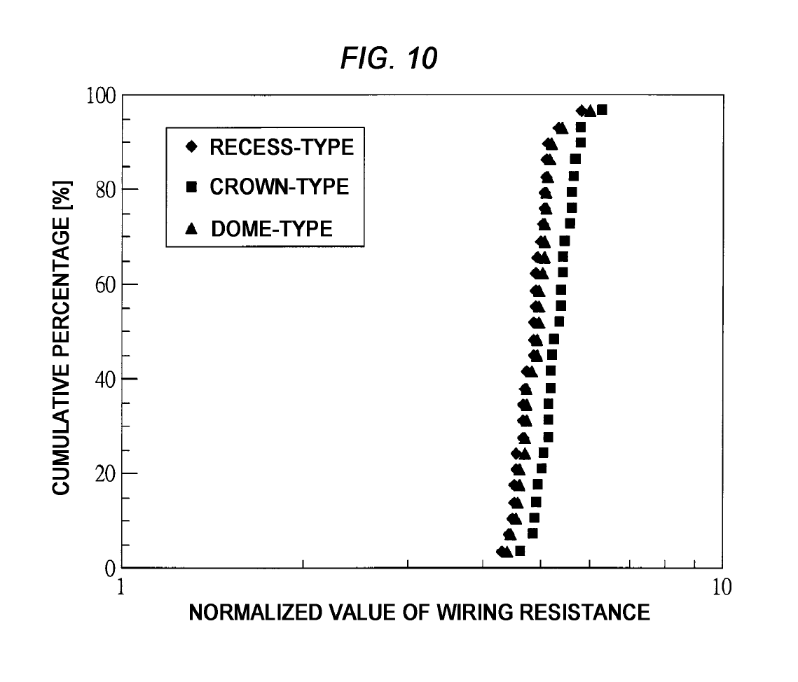

Next, the result of the inspection that the dome-type plug (plug PLG) may make the variation in the value of the wiring leak current smaller than the crown-type plug (plug PLG2). FIG. 10 is a graph showing the relation between the normalized value of the wiring resistance and the cumulative percentage in the recess-type plug (plug PLG1), the crown-type plug (plug PLG2) and the dome-type plug (plug PLG). In FIG. 10, the horizontal axis shows the normalized value of the wiring resistance, and the vertical axis shows the cumulative percentage of test objects. The cumulative percentage means that, for example, when 1000 semiconductor chips are set to be test objects, cumulative percentage 50% represents the variation in the value of the wiring resistance for 500 semiconductor chips, and cumulative percentage 100% represents the variation in the value of the wiring resistance for 1000 semiconductor chips. In the graph shown in FIG. 10, a plot of the graph that stands more vertically means a less variation, and that a plot more shifting toward the left side means a less value of the wiring resistance. Meanwhile, in FIG. 10, the plot of rhombuses corresponds to the recess-type plug (plug PLG1), and the plot of squares corresponds to the crown-type plug (plug PLG2). Moreover, the plot of triangles corresponds to the dome-type plug (plug PLG).

When observing FIG. 10 while considering the above, firstly, since there is no difference among the gradients for the recess-type plug (plug PLG1), the crown-type plug (plug PLG2) and the dome-type plug (plug PLG), they are considered to be equivalent for the variation in the wiring resistance.

On the other hand, from FIG. 10, the absolute value of the wiring resistance in the dome-type plug (plug PLG) becomes smaller than that of the wiring resistance in the crown-type plug (plug PLG2). From this, the dome-type plug (plug PLG) may sufficiently suppress the variation in the wiring resistance between the plug and the wiring as compared with the crown-type plug (plug PLG2) even when the displacement of the wiring due to the photolithographic technique occurs, making it possible to achieve the improvement of the reliability on electric properties in the semiconductor device.

As described above, the dome-type plug (plug PLG) is better than the crown-type plug (plug PLG2) from the standpoint of making the variation in the wiring resistance between the wiring connected to the plug and the plug small, even when the formation displacement of the wiring due to the photolithographic technique occurs.

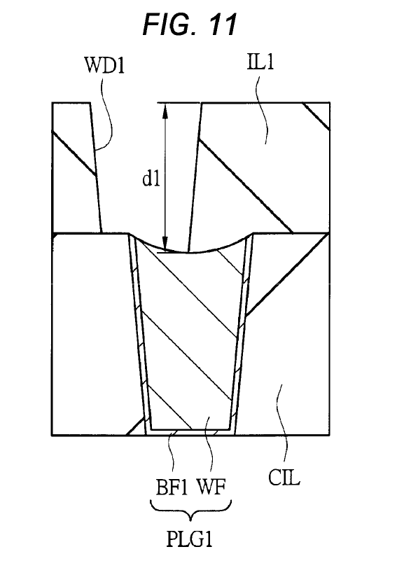

Next, the advantage of the dome-type plug (plug PLG) as compared with the recess-type plug (plug PLG1) will be described. FIG. 11 is a cross-sectional view that illustrates the process of forming the interlayer insulating film IL1 over the contact interlayer insulating film CIL in which the recess-type plug (plug PLG1) has been formed, and forming a wiring trench WD1 having a displacement in the interlayer insulating film IL1. As shown in FIG. 11, since the surface of the plug PLG1 of the recess-type plug (plug PLG1) is more concave than the contact interlayer insulating film CIL, it is necessary to form the wiring trench WD1 down to a depth d1 that is deeper than a depth in a case where the upper surface of the plug PLG1 is not concaved. That is, in order to make the depth d1 of the wiring trench WD1 formed in the interlayer insulating film IL1 deeper, it is necessary to prolong the etching time of the interlayer insulating film IL1. For the etching of the interlayer insulating film IL1, for example, formed from a silicon oxide film, dry etching using plasma is employed. Therefore, by the dry etching for forming the wiring trench WD1 in the interlayer insulating film IL1, the surface of the interlayer insulating film IL1 exposed over the inner, wall of the wiring trench WD1 is unnecessarily damaged by the plasma, to result in the lowering of the reliability of the interlayer insulating film IL1 in which the wiring trench WD1 has been formed.

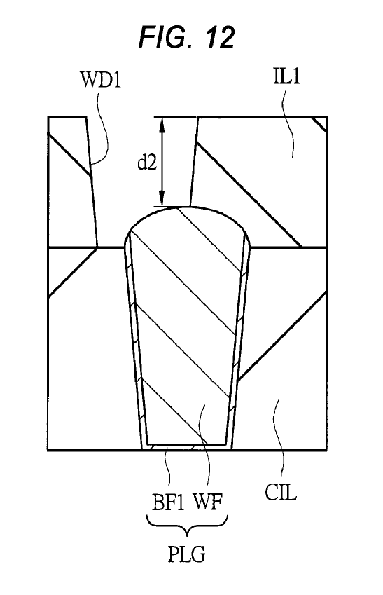

In contrast, FIG. 12 is a cross-sectional view that illustrates the process of forming the interlayer insulating film IL1 over the contact interlayer insulating film CIL in which the dome-type plug (plug PLG) in the Example 1 has been formed, and forming the wiring trench WD1 having the displacement in the interlayer insulating film IL1. As shown in FIG. 12, since the surface of the plug PLG of the dome-type plug (plug PLG) expands in an upwardly convex shape from the contact interlayer insulating film CIL, it is satisfactory to form the wiring trench WD1 so as to have a depth d2 that is shallower than a depth in a case where the upper surface of the plug PLG is not expanded in an upwardly convex shape. That is, since the depth d2 of the wiring trench WD1 formed in the interlayer insulating film IL1 is shallower than the depth d1 of the trench formed in the recess-type plug (plug PLG1), the etching time of the interlayer insulating film IL1 may be shortened. As the result, plasma damage at the surface of the interlayer insulating film IL1 exposed over the inner wall of the wiring trench WD1 may be lowered when forming the wiring trench WD1 in the interlayer insulating film IL1. Consequently, according to the Example 1, it is possible to lower the plasma damage given to the surface of the interlayer insulating film IL1 even when the formation position of the wiring trench WD1 displaces, and to improve the reliability of the semiconductor device.

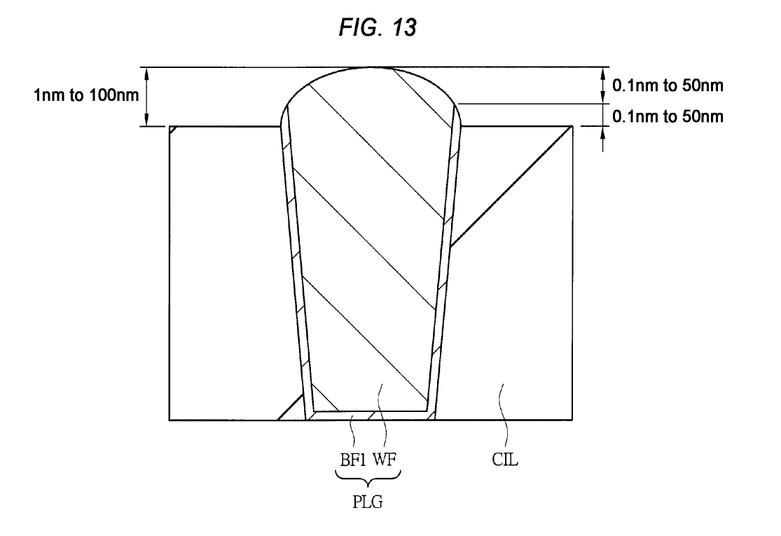

The Example 1 is characterized in that the dome-type plug (plug PLG) is formed, and, in the dome-type plug (plug PLG), the specific dimension will be described for the top edge portion having the dome-like shape that expands in an upwardly convex shape from the contact interlayer insulating film CIL. FIG. 13 is a cross-sectional view showing the structure of the dome-type plug (plug PLG) in the Example 1. In FIG. 13, the interval between the top edge portion (peak portion) in a dome-like shape expanding in an upwardly convex shape formed in the dome-type plug (plug PLG) and the surface (upper surface) of the contact interlayer insulating film CIL is, for example, 1 to 100 nm. The projecting part of the dome-type plug (plug PLG) is mainly formed by polishing the contact interlayer insulating film CIL, and is, for example, around 1 to 100 nm when considering the variation in the polishing amount of the contact interlayer insulating film CIL depending on regions. For example, when setting the variation in the polishing amount of the contact interlayer insulating film CIL to be 10% of the polishing amount, when polishing the contact interlayer insulating film CIL of 100 nm, the variation becomes 10 nm. When it is at the level of around 10 nm, the variation in the projecting part to be formed may also be suppressed to a level that generates no problem.

Furthermore, there is another reason for setting the interval between the top edge portion (peak portion) of a dome-like shape and the surface (upper surface) of the contact interlayer insulating film CIL to be 100 nm or less. For example, increasing the polishing amount of the contact interlayer insulating film CIL means that the thickness of the contact interlayer insulating film CIL to be previously deposited is also made thick. On this occasion, a contact hole is formed in the thick contact interlayer insulating film CIL, and a tungsten film is embedded into the contact hole to form the plug PLG. But, since the aspect ratio (height/length of the bottom surface) of the contact hole becomes large, it becomes hard for the tungsten film to be sufficiently embedded. That is, when forming the contact interlayer insulating film CIL in a thick state while taking the polishing amount thereof into consideration, the formation of the plug PLG becomes difficult. Consequently, the polishing amount of the contact interlayer insulating film CIL is set to be 100 nm or less. As the result, the interval between the top edge portion (peak portion) of a dome-like shape and the surface (upper surface) of the contact interlayer insulating film CIL is, for example, 1 to 100 nm.

The characteristic of the dome-type plug (plug PLG) lies in a point that upwardly convex dome-like shape is formed so that the height of the top edge portion of the barrier conductive film BF1 is higher than the surface of the contact interlayer insulating film CIL and the height of the top edge portion (peak portion) of the tungsten film WF is higher than that of the top edge portion of the barrier conductive film BF1. Accordingly, it is also necessary to define the height between the contact interlayer insulating film CIL and the top edge portion of the barrier conductive film BF1, and the height between the top edge portion of the barrier conductive film BF1 and the top edge portion of the tungsten film WF. Specifically, the height between the contact interlayer insulating film CIL and the top edge portion of the barrier conductive film BF1 is, for example, 0.1 to 50 nm, and the height between the top edge portion of the barrier conductive film BF1 and the top edge portion of the tungsten film WF is, for example, also 0.1 to 50 nm.

The semiconductor device in the Example 1 is so constituted as described above, and, hereinafter, a method of manufacturing the same will be described while referring to the drawing.

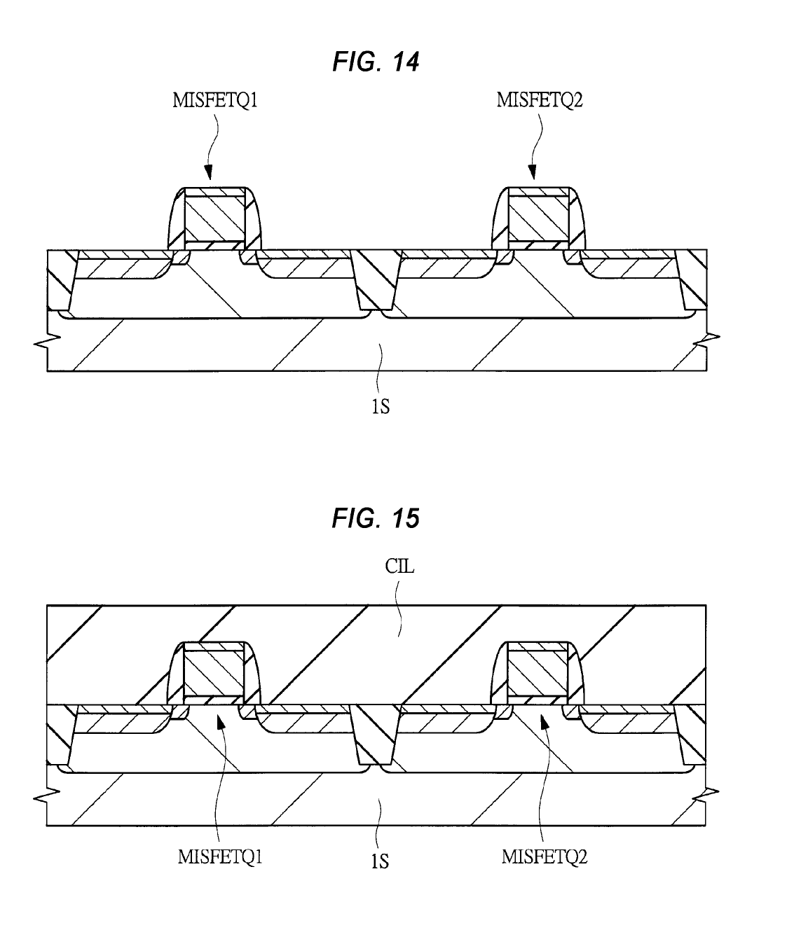

Firstly, by using an ordinary method of manufacturing a semiconductor, as shown in FIG. 14, plural MISFETs are formed over the semiconductor substrate 15. The MISFETs include the n-channel type MISFET Q1 and the p-channel type MISFET Q2. Subsequently, as shown in FIG. 15, over the semiconductor substrate 1S in which the n-channel type MISFET Q1 and the p-channel type MISFET Q2 are formed, the contact interlayer insulating film CIL is formed. The contact interlayer insulating film CIL is formed so as to cover the n-channel type MISFET Q1 and the p-channel type MISFET Q2. Specifically, the contact interlayer insulating film CIL is formed, for example, from a laminated film of an ozone TEOS film formed by a thermal CVD method using ozone and TEOS as raw materials, and a plasma TEOS film formed by a plasma CVD method using TEOS as a raw material. Meanwhile, under the ozone TEOS film, an etching stopper film, for example, constituted of a silicon nitride film may be formed.

The reason why the contact interlayer insulating film CIL is formed from the TEOS film is that the TEOS film is a film having a good covering property for the step of the under layer. The under layer over which the contact interlayer insulating film CIL is to be formed has such uneven state that the MISFET is formed over the semiconductor substrate 1S. That is, since the MISFET is formed over the semiconductor substrate 1S, the gate electrode is formed for the surface of the semiconductor substrate 1S to form an uneven under layer. Accordingly, a film not having a good covering property for the uneven step may not be embedded into a fine unevenness to cause the occurrence of void or the like. Consequently, as the contact interlayer insulating film CIL, the TEOS film is used. Because, in the TEOS film formed from TEOS as the raw material, TEOS as the raw material forms an intermediate before changing into a silicon oxide film to be movable easily at the surface of the formed film, to improve the covering property for the step of the under layer.

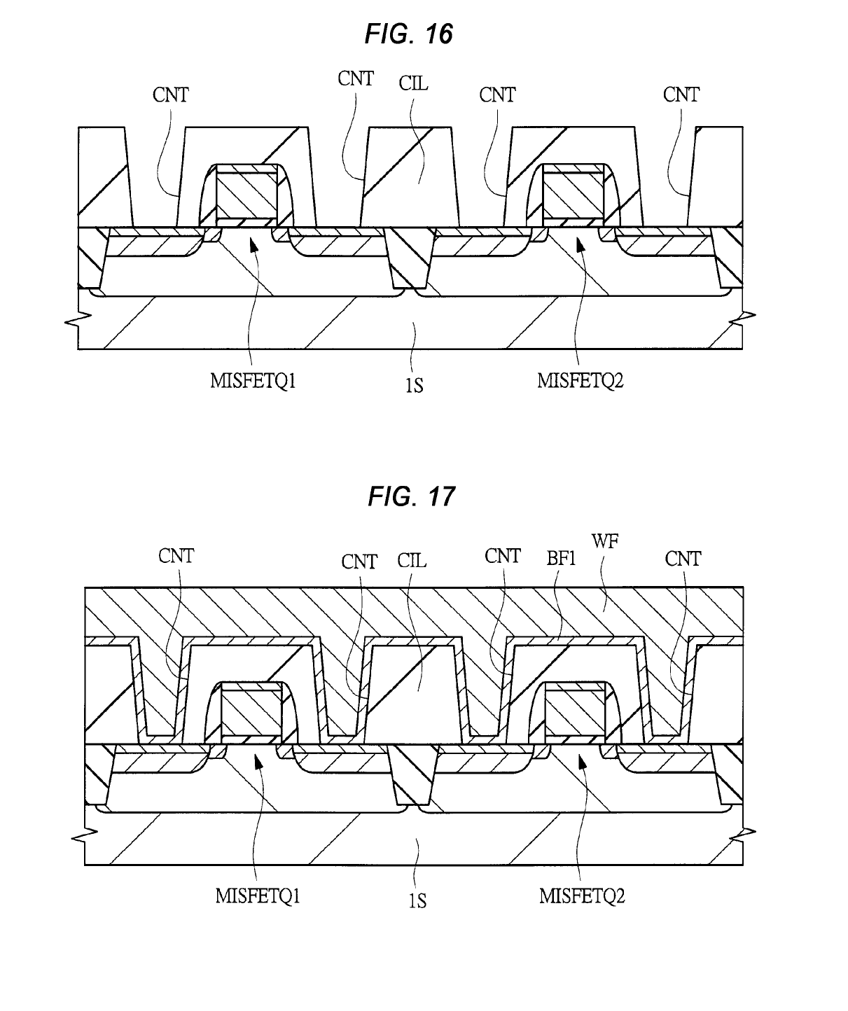

Next, as shown in FIG. 16, by using a photolithographic technique and an etching technique, the contact hole CNT is formed in the contact interlayer insulating film CIL. The contact hole CNT is processed so as to penetrate through the contact interlayer insulating film CIL to reach the source region or drain region of the n-channel type MISFET Q1 or p-channel type MISFET Q2 formed over the semiconductor substrate 1S.

Subsequently, as shown in FIG. 17, a metal film is embedded into the contact hole CNT formed in the contact interlayer insulating film CIL to form the plug PLG. Specifically, over the contact interlayer insulating film CIL in which the contact hole CNT is formed, a titanium/titanium nitride film (a titanium film and a titanium nitride film formed over the titanium film) working as the barrier conductive film BF1 is formed, for example, using sputtering. The titanium/titanium nitride film is a film arranged for inhibiting the diffusion of tungsten constituting the tungsten film into silicon, and for preventing a damage given to the contact interlayer insulating film CIL or the semiconductor substrate 1S by fluorine attack in a CVD method that subjects WF₆ (tungsten fluoride) to a reducing treatment when the tungsten film is constituted. Meanwhile, the barrier conductive film BF1 may be constituted from a single layer film or a laminated film including any of a titanium, titanium nitride and tantalum nitride, in addition to the titanium/titanium nitride film.

Then, over the barrier conductive film BF1, the tungsten film WF is formed. As the result, the barrier conductive film BF1 is formed on the inner wall (side wall and bottom surface) of the contact hole CNT, and the tungsten film WF is formed over the barrier conductive film BF1 so as to be embedded into the contact hole CNT.

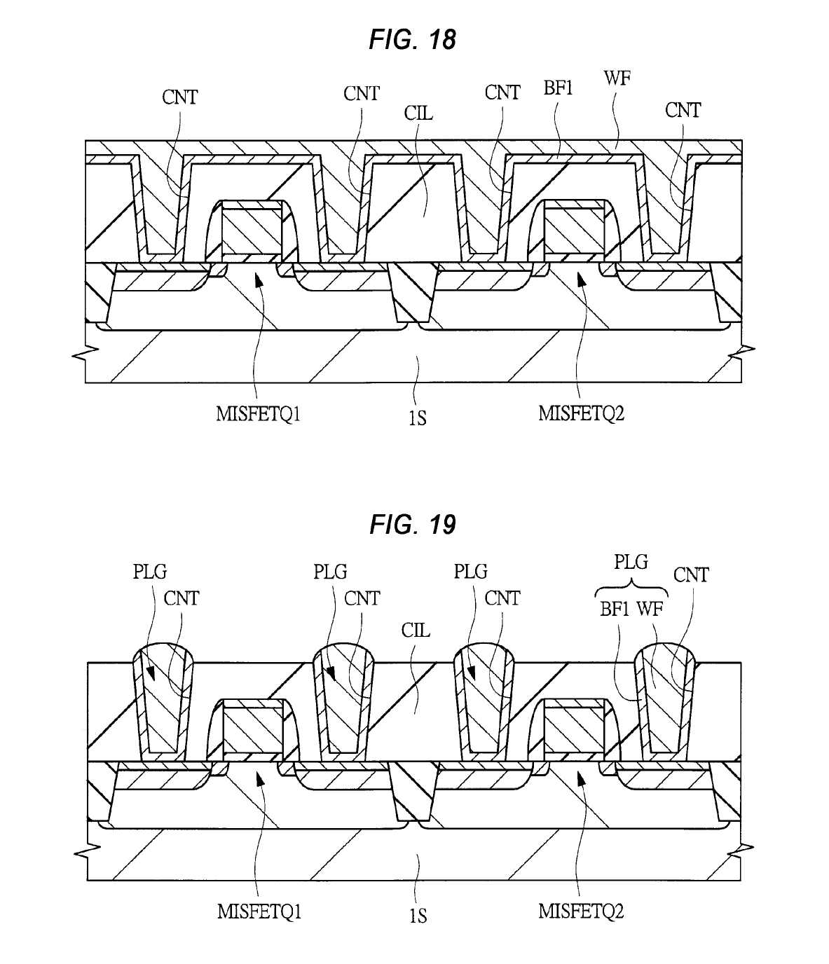

Next, as shown in FIG. 18, the thickness of an unnecessary tungsten film WF formed over the contact interlayer insulating film CIL is thinned by a first polishing process by a chemical mechanical polishing method (CMP method). On this occasion, the first polishing process thins the thickness of the tungsten film WF under such a condition as setting the polishing speed of the tungsten film WF to be higher than that of the contact interlayer insulating film CIL. By setting the polishing speed of the tungsten film WF to be higher than that of the contact interlayer insulating film CIL as described above, the thickness of the tungsten film WF may be thinned in a short period of time. Specifically, in the first polishing process, fumed silica is used as an abrasive grain, and a first slurry containing hydrogen peroxide, iron or an iron compound, and the abrasive grain in a concentration of 5% or less is used to perform chemical mechanical polishing. As the result, the chemical mechanical polishing by the first slurry may actualize a polishing in which the polishing speed of the tungsten film WF is from 10 to 1000 inclusive, when defining the polishing speed of the contact interlayer insulating film CIL as one.

Subsequently, as shown in FIG. 19, by a second polishing process by a chemical mechanical polishing method, the unnecessary tungsten film WF and barrier conductive film BF1 formed over the contact interlayer insulating film CIL are completely removed, and the barrier conductive film BF1 and tungsten film WF are left inside the contact hole CNT, to form the plug PLG. That is, after performing the first polishing process, furthermore, a part of the thinned tungsten film, barrier conductive film BF1 and contact interlayer insulating film CIL are removed by a chemical mechanical polishing method under such a condition as setting the polishing speed of the tungsten film WF to be lower than that of the contact interlayer insulating film CIL, and the barrier conductive film BF1 and tungsten film WF are left in the contact hole CNT, to form the plug. The plug PLG formed at this time is a dome-type plug having an upwardly convex dome-like shape, in which the upper surface thereof projects from the upper surface of the contact interlayer insulating film CIL, the height of the top edge portion of the barrier conductive film BF1 is higher than the upper surface of the contact interlayer insulating film CIL, and the height of the top edge portion of the tungsten film WF is higher than that of the top edge portion of the barrier conductive film BF1.

Specifically, in order to form the dome-type plug (plug PLG), it is necessary to set the condition of the second polishing process as follows. That is, in the second polishing process, fumed silica and colloidal silica are used as an abrasive grain, and a second slurry containing hydrogen peroxide, iron or an iron compound, and the abrasive grain in a concentration of 5% or more are used to perform chemical mechanical polishing. As the result, the chemical mechanical polishing by the second slurry may actualize a polishing in which the polishing speed of the tungsten film WF is 0.1 or more and less than 1, when defining the polishing speed of the contact interlayer insulating film CIL as one. By performing the second polishing process of such condition, the dome-type plug may be formed.

In the second polishing process, the polishing, in which the polishing speed of the tungsten film WF is 0.1 or more and less than 1 when defining the polishing speed of the contact interlayer insulating film CIL is defined as one, is actualized. This means that polishing speed of the contact interlayer insulating film CIL is higher than that of the tungsten film. Accordingly, after the removal of the unnecessary barrier conductive film BF1 and tungsten film. WF formed over the contact interlayer insulating film CIL, the polishing amount of the contact interlayer insulating film CIL surrounding the contact hole CNT becomes larger than the polishing amount of the tungsten film WF embedded in the contact hole CNT. As the result, the height of the top edge portion of the barrier conductive film BF1 and tungsten film WF embedded in the contact hole CNT becomes higher than the surface of the contact interlayer insulating film CIL. Furthermore, in the second polishing process, since the polishing is performed under such condition that may also scrape the tungsten film WF, the corner portions of the tungsten film WF and barrier conductive film BF1 are polished so as to be rounded to form the dome-type plug having an upper surface of an upwardly convex dome-like shape that projects from the upper surface of the contact interlayer insulating film CIL, wherein the height of the top edge portion of the barrier conductive film BF1 is higher than the upper surface of the contact interlayer insulating film CIL, and the height of the top edge portion of the tungsten film WF is higher than that of the top edge portion of the barrier conductive film BF1.

On this occasion, the reason why the height of the top edge portion of the barrier conductive film BF1 is higher than that of the contact interlayer insulating film CIL is that the hydrogen peroxide contained in the second slurry used for the second polishing process does not dissolve the titanium/titanium nitride film constituting the barrier conductive film BF1. That is, in the second polishing process, both the mechanical polishing by the abrasive grain and the chemical polishing by a chemical reaction with a solution (hydrogen peroxide) are used, but, since the barrier conductive film BF1 is not dissolved in hydrogen peroxide, the barrier conductive film BF1 is mainly polished in the second polishing process by the mechanical polishing with the abrasive grain. In the mechanical polishing, since it is difficult to polish the barrier conductive film BF1 down to the lower side of the upper surface of the contact interlayer insulating film CIL, the height of the top edge portion of the barrier conductive film BF1 is higher than that of the upper surface of the contact interlayer insulating film CIL.

And, the purpose of requiring such condition in the second polishing process that the polishing speed of the tungsten film WF is 0.1 or more and less than 1 when defining the polishing speed of the contact interlayer insulating film CIL as one is as follows. That is, the reason why the condition is set to be less than one is that it is necessary to form the upwardly convex dome-like shape by setting the polishing speed of the contact interlayer insulating film CIL to be higher than that of the tungsten film WF. On this occasion, the polishing speed of the tungsten film WF is set so as to be less than one at the initial stage, but, the polishing speed has such a property as being heightened because the temperature of the polishing surface rises along with the elongation of the polishing time of the tungsten film WF. Accordingly, even when it is set so as to give a polishing speed of less than one at the initial stage, the speed may become one or more when the polishing time is elongated. However, by setting the polishing speed at the initial stage to be less than one, a condition in which the polishing speed of the tungsten film WF is smaller than that of the contact interlayer insulating film CIL is actualized and the dome-type plug may be formed. That is, the dome-type plug may be formed when the polishing speed of the tungsten film WF becomes less than one at a stage close to the initial stage among stages from the initial to the final stages of the second polishing process, when defining the polishing speed of the contact interlayer insulating film CIL as one.

On the other hand, the purpose of setting the polishing speed of the tungsten film WF to be 0.1 or more when the polishing speed of the contact interlayer insulating film CIL is set to be one in the second polishing process is that an unnecessary tungsten film WF is not to be left over the contact interlayer insulating film CIL. For example, when the polishing speed of the tungsten film WF becomes less than 0.1, the tungsten film WF tends to be left over the contact interlayer insulating film CIL. On this occasion, such a trouble occurs that electrical connection of adjacent plugs generates via the tungsten film WF left over the contact interlayer insulating film CIL. Furthermore, the tungsten film WF left over the contact interlayer insulating film CIL may peel off to form a foreign material to lower the yield in the process of manufacturing the semiconductor device. Consequently, in the second polishing process, the polishing speed of the tungsten film WF is set to be 0.1 or more when defining the polishing speed of the contact interlayer insulating film CIL as one.

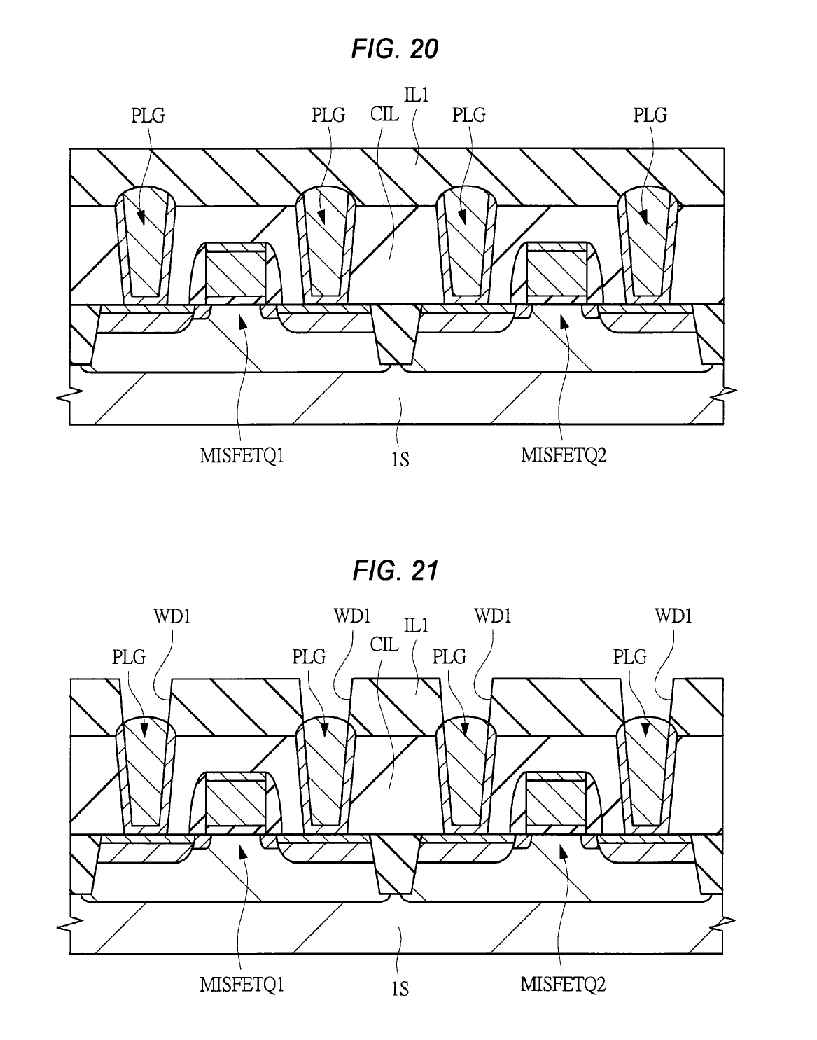

By performing the second polishing process in a manner as described above, the plug PLG being the dome-type plug may be formed. Next, a process, in which a copper wiring is formed using a single damascene method, will be described. As shown in FIG. 20, the interlayer insulating film IL1 is formed over the contact interlayer insulating film CIL in which the plug PLG is formed. The interlayer insulating film IL1 is formed, for example, from a silicon oxide film, and the silicon oxide film may be formed, for example, by using a CVD method.

Then, as shown in FIG. 21, the trench (wiring trench) WD1 is formed in the interlayer insulating film IL1 by using a photolithographic technique and an etching technique. The trench WD1 is formed so that it penetrates through the interlayer insulating film IL1 constituted from a silicon oxide film, and that the bottom surface thereof reaches the upper surface of the plug PLG. As the result, the surface of the plug PLG is exposed at the bottom portion of the trench WD1.

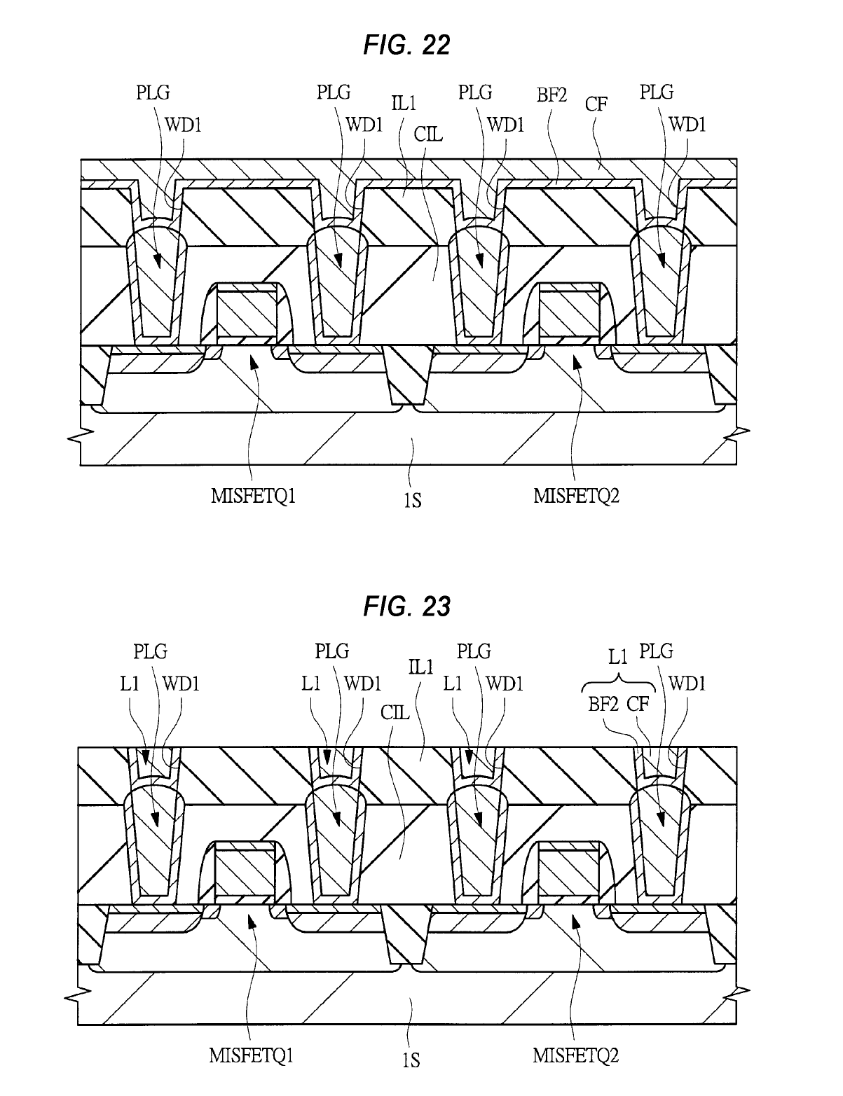

After that, as shown in FIG. 22, over the interlayer insulating film IL1 in which the trench WD1 is formed, a barrier conductive film BF2 is formed. Specifically, the barrier conductive film BF2 is constituted from tantalum (Ta), titanium (Ti), ruthenium (Ru), tungsten (W), manganese (Mn) or nitride or nitride silicide thereof, or a laminated film thereof, which may be formed by using, for example, a sputtering method. In other words, the barrier conductive film BF2 may be formed from either a metal material film constituted from any metal material of tantalum, titanium, ruthenium or manganese, or a compound film constituted from the metal material and any element of Si, N, O and C.

Subsequently, over the barrier conductive film BF2 formed inside the trench WD1 and over the interlayer insulating film IL1, a seed film, for example, constituted from a thin copper film is formed by a sputtering method. Then, by an electrolytic plating using the seed film as an electrode, a copper film CF is formed. The copper film CF is formed so as to be embedded into the trench WD1. The copper film CF is formed, for example, from a film mainly containing copper. Specifically, it is formed from copper (Cu) or a copper alloy (alloy of copper (Cu) with aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), lanthanoid-based metal or actinoid-based metal).

Next, as shown in FIG. 23, an unnecessary barrier conductive film BF2 and copper film CF formed over the interlayer insulating film IL1 are removed by a CMP method. As the result, the wiring L1, in which the barrier conductive film BF2 and the copper film CF are embedded into the trench WD1, may be formed. Meanwhile, in the upper layer of the wiring L1, furthermore, a multilayer wiring is formed, but the description thereof is omitted in the specification. As described above, the semiconductor device in Example 1 may be manufactured.

According to the Example 1, by forming the dome-type plug, even when the displacement of a wiring formed in the upper layer of the dome-type plug occurs due to the pattern displacement in a photolithographic technique, it is possible to suppress the fluctuation of electric properties of the semiconductor device caused by reflecting the displacement of the wiring. For example, even when the displacement of the wiring due to a photolithographic technique occurs, it is possible to sufficiently suppress the short circuit defect between the plug and the wiring originally not to be connected and the variation in the wiring leak current, and to achieve the reliability on electric properties in the semiconductor device. Furthermore, even when the displacement of the wiring due to a photolithographic technique occurs, the change of the wiring resistance between the plug and the wiring may be sufficiently suppressed as compared with the case of the crown-type plug, and, from this standpoint, too, it is possible to achieve the improvement of the reliability on electric properties in the semiconductor device.

### Example 2

Regarding the Example 1, the example, in which the thickness of the tungsten film WF is thinned by the first polishing process as shown in FIG. 18, and, after that, the second polishing process is performed to form the dome-type plug (plug PLG) as shown in FIG. 19, was described. Regarding the Example 2, an example, in which an unnecessary barrier conductive film BF1 and tungsten film WF formed over the contact interlayer insulating film CIL are removed by the first polishing process to expose the surface of the contact interlayer insulating film CIL, and, after performing the first polishing process, the second polishing process is performed to form the dome-type plug (plug PLG), will be described.

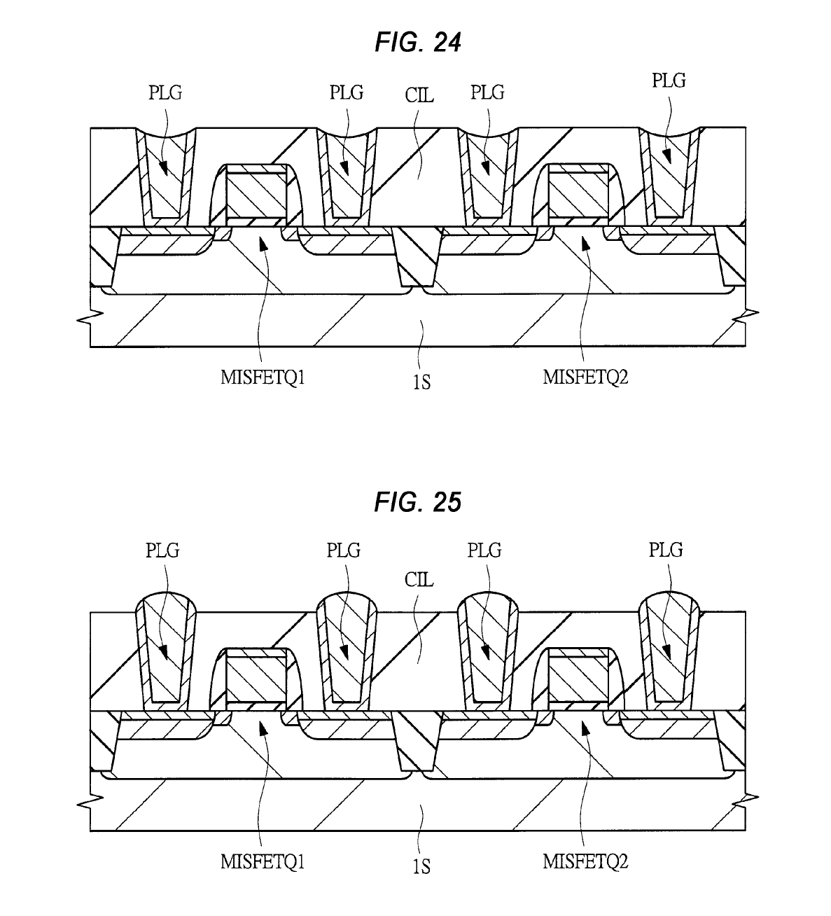

Processes shown in FIGS. 14 to 17 are the same as those in the Example 1. Subsequently, as shown in FIG. 24, an unnecessary tungsten film WF and barrier conductive film BF1 formed over the contact interlayer insulating film CIL are removed by the first polishing process by a chemical mechanical polishing method (CMP method) to expose the surface of the contact interlayer insulating film CIL. On this occasion, the first polishing process is performed under such a condition as setting the polishing speed of the tungsten film WF to be higher than that of the contact interlayer insulating film CIL to thin the thickness of the tungsten film WF. By setting the polishing speed of the tungsten film WF higher than that of the contact interlayer insulating film CIL, the thickness of the tungsten film WF may be thinned in a short period of time. Specifically, in the first polishing process, fumed silica is used as an abrasive grain, and chemical mechanical polishing is performed using a first slurry containing hydrogen peroxide, iron or an iron compound, and the abrasive grain in a concentration of 5% or less. As the result, the chemical mechanical polishing with the first slurry may actualize the polishing in which the polishing speed of the tungsten film WF is from 10 to 1000 inclusive when defining the polishing speed of the contact interlayer insulating film CIL as one.

Next, as shown in FIG. 25, the second polishing process by a chemical mechanical polishing method is performed to polish the contact interlayer insulating film CIL exposed by performing the first polishing process, and a part of the tungsten film WF and the barrier conductive film BF1 embedded in the plug PLG. That is, after performing the first polishing process, furthermore, by the chemical mechanical polishing method, the exposed contact interlayer insulating film CIL and a part of the tungsten film WF and barrier conductive film BF1 embedded in the plug PLG are polished under such a condition as setting the polishing speed of the tungsten film WF to be lower than that of the contact interlayer insulating film CIL. The plug PLG formed on this occasion is the dome-type plug having an upwardly convex dome-like shape having the upper surface that projects from the upper surface of the contact interlayer insulating film CIL, wherein the height of the top edge portion of the barrier conductive film BF1 is higher than that of the upper surface of the contact interlayer insulating film CIL, and the height of the top edge portion of the tungsten film WF is higher than that of the top edge portion of the barrier conductive film BF1.

Specifically, for the purpose of forming the dome-type plug (plug PLG), the following condition is necessary in the second polishing process. That is, in the second polishing process, a chemical mechanical polishing is performed using fumed silica and colloidal silica as the abrasive grain, and the second slurry containing hydrogen peroxide, iron or an iron compound, and the abrasive grain in a concentration of 5% or more. As the result, in the chemical mechanical polishing with the second slurry, a polishing, in which the polishing speed of the tungsten film WF is 0.1 or more and less than 1 when the polishing speed of the contact interlayer insulating film CIL is defined as one, may be actualized. By performing the second polishing process of the condition, the dome-type plug may be formed.

Subsequent processes are the same as those in the Example shown in FIGS. 20 to 23. As described above, the semiconductor device in the Example 2 may be manufactured.

According to the Example 2, by forming the dome-type plug, even when the displacement of a wiring formed in the upper layer of the dome-type plug occurs due to the pattern displacement in a photolithographic technique, it is possible to suppress the fluctuation of electric properties of the semiconductor device caused by reflecting the displacement of the wiring. For example, even when the displacement of the wiring due to a photolithographic technique occurs, it is possible to sufficiently suppress the short circuit defect between the plug and the wiring originally not to be connected and the variation in the wiring leak current, to achieve the reliability on electric properties in the semiconductor device. Furthermore, even when the displacement of the wiring due to a photolithographic technique occurs, the change of the wiring resistance between the plug and the wiring may be sufficiently suppressed as compared with the case of the crown-type plug, and, from this standpoint, too, it is possible to achieve the improvement of the reliability on electric properties in the semiconductor device.

### Example 3

Regarding the Example 1, the example, in which the first polishing process and the second polishing process are performed to form the dome-type plug, was described, but, in the Example 3, an example, in which no first polishing process is performed and a second polishing process is performed from the initial stage to form the dome-type plug, will be described.

It is the same as the Example 1 until the processes shown in FIGS. 14 to 17. Subsequently, as shown in FIG. 19, the second polishing process is performed for the barrier conductive film BF1 and tungsten film WF formed over the contact interlayer insulating film CIL. In the second polishing process, an unnecessary tungsten film WF and barrier conductive film BF1 formed over the contact interlayer insulating film CIL are removed to expose the surface of the contact interlayer insulating film CIL, and, further, a part of the exposed contact interlayer insulating film CIL is removed to form the dome-type plug (plug PLG).

Specifically, in order to form the dome-type plug (plug PLG), it is necessary to set the condition of the second polishing process as described below. That is, in the second polishing process, fumed silica and colloidal silica are used as an abrasive grain, and a second slurry containing hydrogen peroxide, iron or an iron compound, and the abrasive grain in a concentration of 5% or more is used to perform the chemical mechanical polishing. As the result, the chemical mechanical polishing with the second slurry may actualize the polishing in which the polishing speed of the tungsten film WF is 0.1 or more and less than 1 when the polishing speed of the contact interlayer insulating film CIL is defined as one. By performing the second polishing process of the condition, the dome-type plug may be formed.

Subsequent processes are the same as those in the Example 1 shown in FIGS. 20 to 23. As described above, the semiconductor device in the Example 3 may be manufactured.

In the Example 3, too, by forming the dome-type plug, even when the displacement of a wiring formed in the upper layer of the dome-type plug occurs due to the pattern displacement due to a photolithographic technique, it is possible to suppress the fluctuation of electric properties of the semiconductor device caused by reflecting the displacement of the wiring. For example, even when the displacement of the wiring due to a photolithographic technique occurs, it is possible to sufficiently suppress the short circuit defect between the plug and the wiring originally not to be connected and the variation in the wiring leak current, to achieve the reliability on electric properties in the semiconductor device. Furthermore, even when the displacement of the wiring due to a photolithographic technique occurs, the change of the wiring resistance between the plug and the wiring may be sufficiently suppressed as compared with the case of the crown-type plug, and, from this standpoint, too, it is possible to achieve the improvement of the reliability on electric properties in the semiconductor device.

Hitherto, the invention achieved by the present inventor is specifically described on the basis of Examples thereof, but, needless to say, the present invention is not limited to these Examples, but is variously changeable within the range that does not depart from the gist thereof.

Here, advantages of the method of manufacturing a semiconductor device described in the Examples 1 and 2 will be described. For example, over a semiconductor substrate, a plug and wiring are formed by patterning utilizing a photolithographic technique, and, on this occasion, it is necessary to perform the registration between the plug and the wiring. For the purpose of performing the registration between the plug and the wiring, the registration mark formed for the semiconductor substrate is used to perform patterning by a photolithographic technique. Accordingly, the formation of a satisfactory registration mark for the semiconductor substrate is necessary.

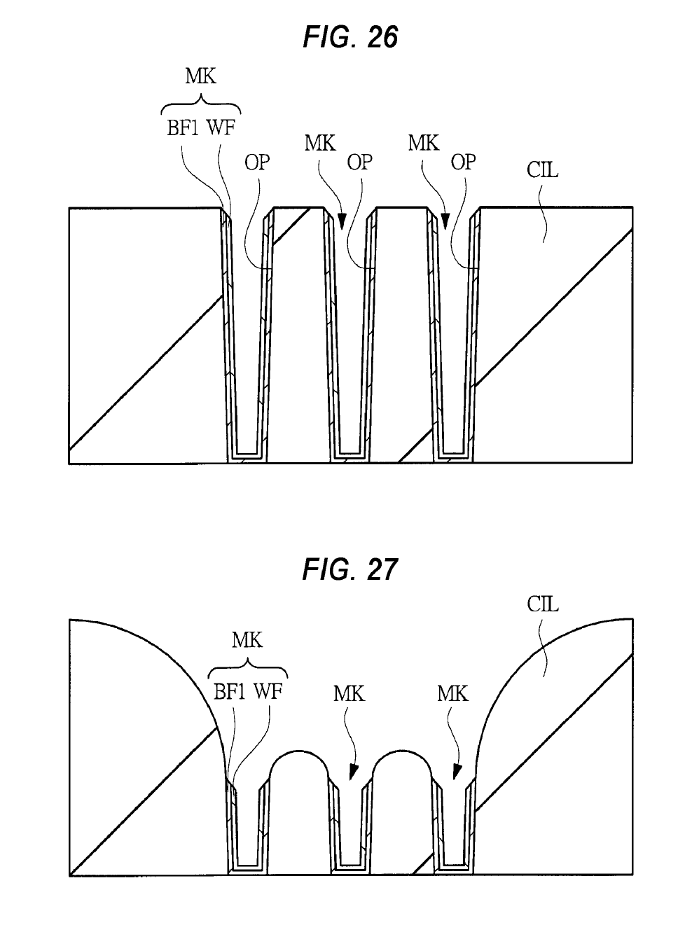

FIG. 26 is a cross-sectional view showing an example of a registration mark MK formed for the semiconductor substrate. As shown in FIG. 26, the registration mark MK is constituted by forming the barrier conductive film BF1 and the tungsten film WF on the inner wall of an opening OP formed in the contact interlayer insulating film CIL. That is, the registration mark MK is formed using the formation process of the plug. Here, the point of difference between the registration mark MK and the plug is that the diameter of the opening OP for which the registration mark MK is formed is sufficiently larger than the diameter of the contact hole for which the plug is formed. Consequently, the opening OP for the registration mark MK is not filled up with the tungsten film WF, but the tungsten film WF is formed only on the inner wall of the opening OP. When forming the registration mark MK, too, an unnecessary barrier conductive film BF1 and tungsten film WF formed over the contact interlayer insulating film CIL are removed by a chemical mechanical polishing in the same manner as in the formation process of the plug.

Here, when removing an unnecessary barrier conductive film BF1 and an unnecessary tungsten film WF formed over the contact interlayer insulating film CIL, a long time polishing of tungsten film WF and barrier conductive film BF1 leads to the occurrence of a phenomenon referred to as erosion. The phenomenon referred to as the erosion is such a phenomenon that the corner portion of the contact interlayer insulating film CIL is scraped along with the tungsten film WF resulting from mechanical pressure applied to the corner portion of the opening OP. FIG. 27 is a cross-sectional view showing the state where the erosion occurs for the registration mark MK. As shown in FIG. 27, it is understood that the contact interlayer insulating film CIL is removed and the shape of the registration mark MK is deteriorated. The erosion is caused by the fact that the inside of the opening OP is not filled up with the tungsten film WF because of a large diameter of the opening OP for which the registration mark MK is to be constituted. That is, when the tungsten film WF is polished in such a state that the tungsten film WF is formed only on the inner wall of the opening OP, the tungsten film WF formed at the corner portion of the opening OP is removed and the contact interlayer insulating film CIL is exposed. Since the polishing pressure is high at the corner portion of the opening OP, not only the polishing of the tungsten film WF, but also the polishing of the contact interlayer insulating film CIL progresses. As the result, the erosion, in which the contact interlayer insulating film CIL is scraped, occurs. A longer polishing time of the tungsten film WF results in a larger erosion.

Here, in the Examples 1 and 2, the polishing of the tungsten film WF is performed in the first and second polishing processes. The first polishing process is performed under the condition in which the polishing speed of the tungsten film WF is from 10 to 1000 inclusive when defining the polishing speed of the contact interlayer insulating film CIL as one. That is, the polishing speed of the tungsten film WF is higher. In other words, the time necessary for removing an unnecessary tungsten film WF may be shortened, and, therefore, the erosion in the region where the registration mark MK is formed may be made small. Consequently, according to the method of manufacturing a semiconductor device in the Examples 1 and 2, since the deterioration of the registration mark MK caused by the erosion may be suppressed, it is possible to improve the registration accuracy between the plug and the wiring, and to prevent the displacement of the formation position of the wiring relative to the formation position of the plug. As a result, due to the synergistic effect with the formation of the dome-type plug, the reliability on electric properties in the semiconductor device may be improved.

Finally, the difference of the present invention from the invention in Patent Document 1 will be described. Patent Document 1 describes the technique for improving the reliability on the electric connection between the wiring and the plug formed over the interlayer insulating film by making the plug formed over the semiconductor substrate higher than the interlayer insulating film. As the method of manufacturing the plug, it describes that, firstly, the first polishing is performed under such a condition that the polishing speed of the tungsten film is higher than that of the interlayer insulating film, and that, subsequently, the second polishing is performed under such a condition that the polishing speed of the tungsten film is lower than that of the interlayer insulating film. On this occasion, in the first polishing, an abrasive grain including alumina (Al₂O₃), and acid or a basic material such as hydrogen peroxide (H₂O₂), potassium hydroxide (KOH) or ammonium hydroxide (NH₄OH) are used, and, in the second polishing, an abrasive grain including colloidal silica, hydrogen peroxide (H₂O₂), and a basic material such as potassium hydroxide (KOH) are used. In the second polishing, the polishing speed of the tungsten film is 50 Å/min, and the polishing speed of the interlayer insulating film is 2500 Å/min.

As described above, Patent Document 1 describes the technique for making the plug higher than the interlayer insulating film. However, although the tungsten film is embedded in the plug, there is no description about the barrier conductive film. Accordingly, differing from the invention of the present application, it does not describe such a constitution that the plug is a dome-type plug having an upwardly convex dome-like shape in which the upper surface thereof projects from the upper surface of the contact interlayer insulating film CIL, that the height of the top edge portion of the barrier conductive film BF1 is higher than that of the upper surface of the contact interlayer insulating film CIL, and that the height of the top edge portion of the tungsten film WF is higher than that of the top edge portion of the barrier conductive film BF1. Consequently, Patent Document 1 neither describes nor suggests that the height of the top edge portion of the barrier conductive film is higher than that of the surface of the contact interlayer insulating film.

Furthermore, in Patent Document 1, upon the second polishing, an abrasive grain including colloidal silica, hydrogen peroxide (H₂O₂), a basic material such as potassium hydroxide (KOH) are used. However, the basic material such as potassium hydroxide (KOH) has such a property as dissolving a titanium film constituting the barrier conductive film. Accordingly, although Patent Document 1 originally does not describe the barrier conductive film, when supposing a case where the barrier conductive film is formed, by the second polishing, not only a mechanical polishing by the abrasive grain, but also a chemical polishing by the basic material acts on the barrier conductive film. Consequently, when only the mechanical polishing acts, the height of the barrier conductive film is not lowered than the surface of the contact interlayer insulating film, however, when the chemical polishing by the solution also acts, it is considered that the solution penetrates from the surface of the plug also to the barrier conductive film, which is formed at a lower position than the surface of the contact interlayer insulating film, to remove the same. Consequently, in the second polishing according to Patent Document 1, it is highly possible that the height of the top edge portion of the barrier conductive film becomes lower than that of the surface of the contact interlayer insulating film. This also means that the use of the technique described in Patent Document 1 hardly actualizes the constitution that is characteristic of the present invention.

Furthermore, Patent Document 1 describes that the polishing speed of the tungsten film in the second polishing is set to be 50 Å/min, and that the polishing speed of the interlayer insulating film is set to be 2500 Å/min. That is, the polishing speed of the tungsten film is 0.02 when defining the polishing speed of the interlayer insulating film as one. On the other hand, in the present invention, the polishing speed of the tungsten film is 0.1 or more and less than 1 when defining the polishing speed of the contact interlayer insulating film as one. That is, the polishing speed of the tungsten film described in Patent Document 1 is considerably lower than that in the present invention. This means that the time necessary for removing the tungsten film becomes longer. Therefore, it is possible to say that, in Patent Document 1, the erosion becomes large, and that the deterioration of the shape of the registration mark tends to occur. As the result, the occurrence of the deterioration in the registration accuracy is considered.

Furthermore, when the polishing speed of the tungsten film becomes unnecessarily slow, for example, when it becomes less than 0.1, the tungsten film tends to be left over the contact interlayer insulating film. On this occasion, such a defect occurs that adjacent plugs are electrically coupled via the tungsten film left over the contact interlayer insulating film. Moreover, the tungsten film left over the contact interlayer insulating film peels off to be a foreign material, to lead to lowering the yield of the semiconductor device in the manufacturing process.

In contrast, in the present invention, since the polishing speed of the tungsten film is 0.1 or more and less than 1 when defining the polishing speed of the contact interlayer insulating film as one, such significant effects may be obtained that the deterioration in the shape of the registration mark due to the erosion and the generation of the residue of the tungsten film over the contact interlayer insulating film may be suppressed, which may not be actualized according to Patent Document 1.

The present invention is widely utilized in manufacturing industries that manufacture semiconductor devices.

1. A semiconductor device comprising:
(a) a semiconductor element formed over a semiconductor substrate;
(b) an interlayer insulating film formed over the semiconductor substrate so as to cover the semiconductor element;
(c) a plug penetrating through the interlayer insulating film and electrically coupled to the semiconductor element; and
(d) a wiring formed over the interlayer insulating film and electrically coupled to the plug,
the plug having (c2) a barrier conductive film which is formed on an inner wall of a contact hole formed in the interlayer insulating film, and (c3) a first conductive film formed over the barrier conductive film so as to fill the contact hole, wherein
an upper surface of plug has an upwardly convex dome-like shape projecting from an upper surface of the interlayer insulating film;
a height of a top edge portion of the barrier conductive film is larger than that of the upper surface of the interlayer insulating film; and
a height of a top edge portion of the first conductive film is larger than that of a top edge portion of the barrier conductive film.

2. The semiconductor device according to claim 1, wherein
the height of the top edge portion of the first conductive film is larger than that of the upper surface of the interlayer insulating film by from 1 to 100 nm.

3. The semiconductor device according to claim 2, wherein
the height of the top edge portion of the first conductive film is larger than that of the top edge portion of the barrier conductive film by from 0.1 to 50 nm, and
the height of the top edge portion of the barrier conductive film is larger than that of the upper surface of the interlayer insulating film by from 0.1 to 50 nm.

4. The semiconductor device according to claim 1, wherein
the barrier conductive film is a film comprising any of titanium, titanium nitride and tantalum nitride.

5. The semiconductor device according to claim 1, wherein
the first conductive film is constituted of a tungsten film.

6. A method of manufacturing a semiconductor device comprising the steps of:
(a) forming a semiconductor element over a semiconductor substrate;
(b) forming an interlayer insulating film over the semiconductor substrate so as to cover the semiconductor element;
(c) forming a contact hole penetrating through the interlayer insulating film;
(d) forming a barrier conductive film over the interlayer insulating film including an inside of the contact hole;
(e) forming a first conductive film over the barrier conductive film so as to fill an inside of the contact hole;
(f) thinning the thickness of the first conductive film by a chemical mechanical polishing method; and
(g), after the step (f), forming a plug by removing the thinned first conductive film, the barrier conductive film and a part of the interlayer insulating film by a chemical mechanical polishing method under a condition in which a polishing speed of the first conductive film is lower than that of the interlayer insulating film, and by leaving the barrier conductive film and the first conductive film in the contact hole, wherein
an upper surface of the plug formed in the step (g) has an upwardly convex dome-like shape projecting form an upper surface of the interlayer insulating film;
a height of the top edge portion of the barrier conductive film is larger than that of the upper surface of the interlayer insulating film; and
a height of the top edge portion of the first conductive film is larger than that of the top edge portion of the barrier conductive film.

7. The method of manufacturing a semiconductor device according to claim 6, wherein,
the step (f) thins a thickness of the first conductive film under such a condition as setting a polishing speed of the first conductive film to be higher than that of the interlayer insulating film.

8. The method of manufacturing a semiconductor device according to claim 6, wherein
the step (f) performs a chemical mechanical polishing method using a first slurry; and
the step (g) performs a chemical mechanical polishing method using a second slurry, and wherein
the first slurry is a slurry that uses fumed silica as an abrasive grain and contains hydrogen peroxide, iron or an iron compound and the abrasive grain in a concentration of 5% or less; and
the second slurry is a slurry that uses fumed silica and colloidal silica as an abrasive grain and contains hydrogen peroxide, iron or an iron compound and the abrasive grain in a concentration of 5% or more.

9. The method of manufacturing a semiconductor device according to claim 6, wherein
the step (f) performs a chemical mechanical polishing method using a first slurry; and
the step (g) performs a chemical mechanical polishing method using a second slurry, and wherein,
in the chemical mechanical polishing with the first slurry, a polishing speed of the first conductive film is from 10 to 1000 inclusive when a polishing speed of the interlayer insulating film is defined as one; and
in the chemical mechanical polishing with the second slurry, the polishing speed of the first conductive film is 0.1 or more and less than one when the polishing speed of the interlayer insulating film is defined as one.

10. The method of manufacturing a semiconductor device according to claim 6, wherein,
in the plug formed in the step (g), the height of the top edge portion of the first conductive film is formed larger than that of the upper surface of the interlayer insulating film by from 1 to 100 nm.

11. The method of manufacturing a semiconductor device according to claim 6, wherein,
in the plug formed in the step (g), the height of the top edge portion of the first conductive film is formed larger than that of the top edge portion of the barrier conductive film by from 0.1 to 50 nm; and
the height of the top edge portion of the barrier conductive film is formed larger than that of the upper surface of the interlayer insulating film by from 0.1 to 50 nm.

12. The method of manufacturing a semiconductor device according to claim 6, wherein,
the step (d) forms the barrier conductive film from a film comprising any of titanium, titanium nitride and tantalum nitride.

13. The method of manufacturing a semiconductor device according to claim 6, wherein,
the step (e) forms the first conductive film from a tungsten film.

14. A method of manufacturing a semiconductor device comprising the steps of:
(a) forming a semiconductor element over a semiconductor substrate;
(b) forming an interlayer insulating film over the semiconductor substrate so as to cover the semiconductor element;
(c) forming a contact hole penetrating through the interlayer insulating film;
(d) forming a barrier conductive film over the interlayer insulating film including an inside of the contact hole;
(e) forming a first conductive film over the barrier conductive film so as to fill the inside of the contact hole;
(f) exposing an upper surface of the interlayer insulating film by removing the first conductive film and the barrier conductive film formed over the interlayer insulating film by a chemical mechanical polishing method while leaving the barrier conductive film and the first conductive film inside the contact hole; and
(g), after the step (f), forming a plug by removing a part of the interlayer insulating film by a chemical mechanical polishing method under a condition in which a polishing speed of the first conductive film is lower than that of the interlayer insulating film, and by leaving the barrier conductive film and the first conductive film in the contact hole, wherein
an upper surface of the plug formed in the step (g) has an upwardly convex dome-like shape projecting from an upper surface of the interlayer insulating film;
a height of the top edge portion of the barrier conductive film is larger than that of the upper surface of the interlayer insulating film; and
a height of the top edge portion of the first conductive film is larger than that of the top edge portion of the barrier conductive film.

15. The method of manufacturing a semiconductor device according to claim 14, wherein
the step (f) is performed under such a condition as setting the polishing speed of the first conductive film to be higher than that of the interlayer insulating film.

16. The method of manufacturing a semiconductor device according to claim 14, wherein
the step (f) performs a chemical mechanical polishing method using a first slurry; and
the step (g) performs a chemical mechanical polishing method using a second slurry, and wherein
the first slurry is a slurry that uses fumed silica as an abrasive grain and contains hydrogen peroxide, iron or an iron compound and the abrasive grain in a concentration of 5% or less; and
the second slurry is a slurry that uses fumed silica and colloidal silica as an abrasive grain and contains hydrogen peroxide, iron or an iron compound and the abrasive grain in a concentration of 5% or more.

17. The method of manufacturing a semiconductor device according to claim 14, wherein
the step (f) performs a chemical mechanical polishing method using a first slurry; and
the step (g) performs a chemical mechanical polishing method using a second slurry, and wherein,
in the chemical mechanical polishing with the first slurry, the polishing speed of the first conductive film is from 10 to 1000 inclusive when the polishing speed of the interlayer insulating film is defined as one; and
in the chemical mechanical polishing with the second slurry, the polishing speed of the first conductive film is 0.1 or more and less than one when the polishing speed of the interlayer insulating film is defined as one.

18. The method of manufacturing a semiconductor device according to claim 14, wherein,
in the plug formed in the step (g), the height of the top edge portion of the first conductive film is formed larger than that of the upper surface of the interlayer insulating film by from 1 to 100 nm.

19. The method of manufacturing a semiconductor device according to claim 14, wherein,
in the plug formed in the step (g), the height of the top edge portion of the first conductive film is formed larger than that of the top edge portion of the barrier conductive film by from 0.1 to 50 nm; and
the height of the top edge portion of the barrier conductive film is formed larger than that of the upper surface of the interlayer insulating film by from 0.1 to 50 nm.

20. The method of manufacturing a semiconductor device according to claim 14, wherein,
the step (d) forms the barrier conductive film from a film comprising any of titanium, titanium nitride and tantalum nitride.

21. The method of manufacturing a semiconductor device according to claim 14, wherein,
the step (e) forms the first conductive film from a tungsten film.

22. A method of manufacturing a semiconductor device comprising the steps of:
(a) forming a semiconductor element over a semiconductor substrate;
(b) forming an interlayer insulating film over the semiconductor substrate so as to cover the semiconductor element;
(c) forming a contact hole penetrating through the interlayer insulating film;
(d) forming a barrier conductive film over the interlayer insulating film including an inside of the contact hole;
(e) forming a first conductive film over the barrier conductive film so as to fill an inside of the contact hole; and
(f) forming a plug by removing the first conductive film and the barrier conductive film which are formed over the interlayer insulating film and a part of the interlayer insulating film by a chemical mechanical polishing method under a condition in which a polishing speed of the first conductive film is set to be lower than that of the interlayer insulating film while leaving the barrier conductive film and the first conductive film inside the contact hole, wherein
an upper surface of the plug formed in the step (f) has an upwardly convex dome-like shape projecting from an upper surface of the interlayer insulating film;
a height of the top edge portion of the barrier conductive film is larger than that of the upper surface of the interlayer insulating film; and
a height of the top edge portion of the first conductive film is larger than that of the top edge portion of the barrier conductive film.
